(19) United States
(12) Patent Application Publication
(10) Pub. No.: US 2024/0196606 A1
(43) Pub. Date: Jun. 13, 2024

(54) MICROELECTRONIC DEVICES INCLUDING STADIUM STRUCTURES, AND RELATED MEMORY DEVICES AND ELECTRONIC SYSTEMS

(71) Applicant: Micron Technology, Inc., Boise, ID (US)

(72) Inventors: Lifang Xu, Boise, ID (US); Harsh Narendrakumar Jain, Boise, ID (US); Indra V. Chary, Boise, ID (US); Richard J. Hill, Boise, ID (US)

(21) Appl. No.: 18/513,430

(22) Filed: Nov. 17, 2023

Related U.S. Application Data
(63) Continuation of application No. 63/387,238, filed on Dec. 13, 2022.

(51) Int. Cl. H10B 41/35; G11C 5/02; G11C 16/04; H10B 41/10; H10B 41/20; H10B 43/10; H10B 43/20; H10B 43/35

(52) U.S. Cl. CPC H10B 41/35; G11C 5/025; G11C 16/0483; H10B 41/10; H10B 41/20; H10B 43/10; H10B 43/20; H10B 43/35

(57) ABSTRACT

A microelectronic device includes a stack structure comprising blocks, additional dielectric slot structures, and a further dielectric slot structure. The stack structure includes alternating tiers of conductive and insulative structures. A block comprises a stadium structure and crest regions. The stadium structure includes staircase structures having steps comprising edges of the tiers. The additional dielectric slot structures individually extend in the first direction across a first of the crest regions and at least partially into the stadium structure. The additional dielectric slot structures are separated from one another in a second direction orthogonal to the first direction and individually vertically extend through the tiers. The further dielectric slot structure extends in the second direction across a second of the crest regions. The further dielectric slot structure intersects at least one of the additional dielectric slot structures and vertically extend through the tiers.

### CROSS-REFERENCE TO RELATED APPLICATION

This application claims the benefit under 35 U.S.C. § 119(e) of U.S. Provisional Patent Application Ser. No. 63/387,238, filed Dec. 13, 2022, the disclosure of which is hereby incorporated herein in its entirety by this reference.

### TECHNICAL FIELD

The disclosure, in various embodiments, relates generally to the field of microelectronic device design and fabrication. More specifically, the disclosure relates to microelectronic devices, memory devices, and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often seek to design architectures that are not only compact, but offer performance advantages, as well as simplified designs.

One example of a microelectronic device is a memory device. Memory devices are generally provided as internal integrated circuits in computers or other electronic devices. There are many types of memory devices including, but not limited to, non-volatile memory devices (e.g., NAND Flash memory devices). One way of increasing memory density in non-volatile memory devices is to utilize vertical memory array (also referred to as a “three-dimensional (3D) memory array”) architectures. A conventional vertical memory array includes strings of memory cells vertically extending through one or more stack structures including tiers of conductive material and insulative material. Each string of memory cells may include at least one select device coupled thereto. Such a configuration permits a greater number of switching devices (e.g., transistors) to be located in a unit of die area (i.e., length and width of active surface consumed) by building the array upwards (e.g., vertically) on a die, as compared to structures with conventional planar (e.g., two-dimensional) arrangements of transistors.

Vertical memory array architectures generally include electrical connections between the conductive material of the tiers of the stack structure(s) of the memory device and control logic devices (e.g., string drivers) so that the memory cells of the vertical memory array can be uniquely selected for writing, reading, or erasing operations. One method of forming such an electrical connection includes forming so-called “staircase” (or “stair step”) structures at edges (e.g., horizontal ends) of the tiers of the stack structure(s) of the memory device. The staircase structure includes individual “steps” defining contact regions for the conductive material of the tiers, upon which conductive contact structures can be positioned to provide electrical access to the conductive material. In turn, conductive routing structures can be employed to couple the contact structures to the control logic devices. Unfortunately, as feature packing densities have increased and margins for formation errors have decreased, conventional fabrication methods and resulting structural configurations have resulted in undesirable defects that can diminish desired memory device performance, reliability, and durability.

### BRIEF DESCRIPTION OF THE DRAWINGS

FIG. 1A is a simplified, longitudinal cross-sectional view of a portion of a microelectronic device structure, in accordance with one embodiment of the disclosure. FIG. 1B is a simplified, longitudinal cross-sectional view, orthogonal to the view of FIG. 1A, of the microelectronic device structure shown in FIG. 1A. FIG. 1C is a simplified, partial top-down view of the microelectronic device structures shown in FIG. 1A.

FIG. 2 is a simplified, partial top-down view of a microelectronic device structure, in accordance with another embodiment of the disclosure.

FIG. 3 is a simplified partial cutaway perspective view of a memory device, in accordance with embodiments of the disclosure.

FIG. 4 is a schematic block diagram illustrating an electronic system, in accordance with embodiments of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessarily limited to memory functionality. Stated another way, and by way of non-limiting example only, the term “memory device” includes not only conventional memory (e.g., conventional volatile memory, such as conventional dynamic random access memory (DRAM); conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, the term “configured” refers to a size, shape, material composition, orientation, and arrangement of one or more of at least one structure and at least one apparatus facilitating operation of one or more of the structure and the apparatus in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., regions, structures, devices) described as “neighboring” one another means and includes features of the disclosed identity (or identities) that are located most proximate (e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, spatially relative terms, such as “beneath,” “below,” “lower,” “downward,” “bottom,” “above,” “upper,” “upward,” “top,” “front,” “rear,” “left,” “right,” “side,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, any ordinal terms, such as “first,” “second,” etc., is used for clarity and convenience in understanding the disclosure and accompanying drawings or to distinguish one claimed construct from another, and do not connote or depend on any specific sequence, preference, time, uniqueness, or order, except where the context clearly indicates otherwise.

As used herein, the singular forms “a,” “an,” and “the” are intended to include the plural forms as well, unless the context clearly indicates otherwise.

As used herein, “and/or” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative material” means and includes electrically insulative material, such as one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative structure may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including insulative material.

As used herein, the term “semiconductor material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

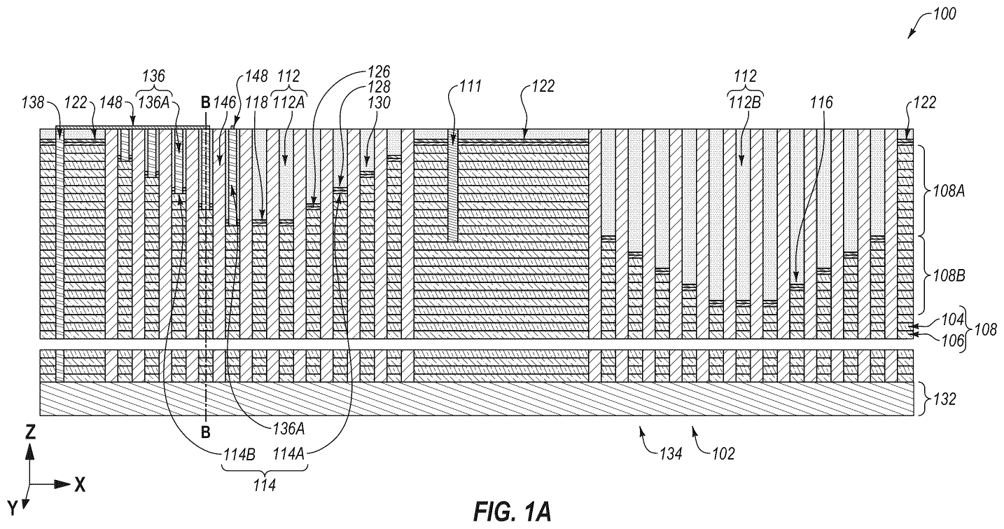

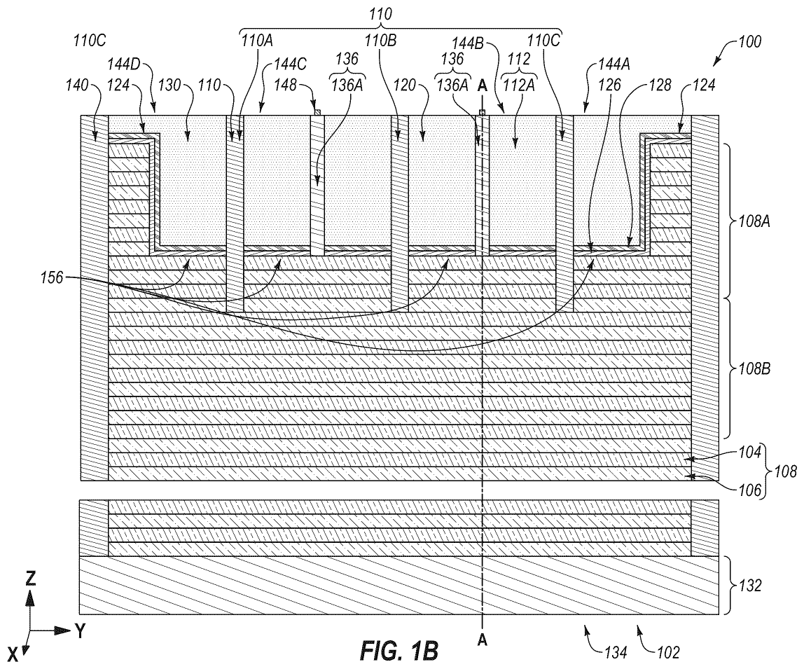

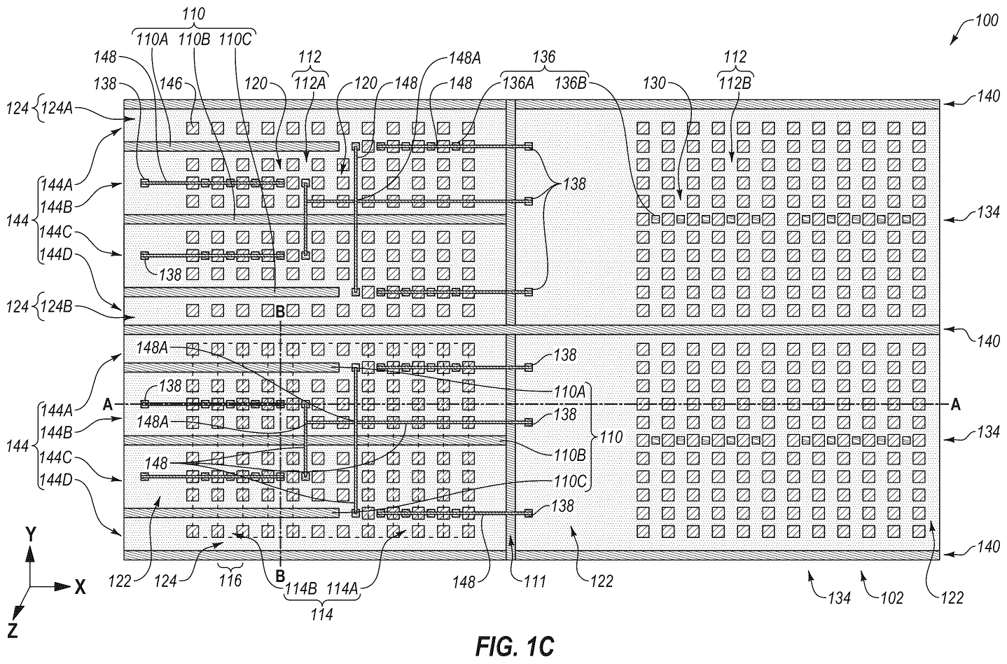

FIGS. 1A through 1C are various views (described in further detail below) illustrating a microelectronic device structure 100 for a microelectronic device (e.g., a memory device, such as a 3D NAND Flash memory device), in accordance with embodiments of the disclosure. With the description provided below, it will be readily apparent to one of ordinary skill in the art that the structures (e.g., the microelectronic device structure 100) and devices (e.g., microelectronic devices) described herein may be employed in various relatively larger devices and/or systems. For clarity and ease of understanding the drawings and associated description, not all features (e.g., regions, structures, materials, devices) of the microelectronic device structure 100 depicted in one or more of FIGS. 1A through 1C.

FIG. 1A is a simplified, partial longitudinal cross-sectional view of the microelectronic device structure 100. FIG. 1B is a simplified, partial longitudinal cross-sectional view, orthogonal to the view of FIG. 1A, of the microelectronic device structure 100 depicted in FIG. 1A. FIG. 1C is a simplified, partial top-down view of the microelectronic device structure 100 depicted in FIG. 1A. The view of the microelectronic device structure 100 shown in FIG. 1A is about the dashed line A-A depicted in each of FIG. 1B and FIG. 1C. The view of the microelectronic device structure 100 shown in FIG. 1B is about the dashed line B-B depicted in each of FIG. 1A and FIG. 1C.

As shown in FIG. 1A and FIG. 1B, the microelectronic device structure 100 may include a stack structure 102 including a vertically alternating (e.g., in a Z-direction) sequence of insulative structures 104 and conductive structures 106 arranged in tiers 108. The insulative structures 104 may be vertically interleaved with the conductive structures 106. Each of the tiers 108 of the stack structure 102 may individually include a conductive structure 106 vertically neighboring (e.g., directly vertically adjacent) an insulative structure 104. The stack structure 102 may be formed to include any desired quantity of the tiers 108. By way of non-limiting example, the stack structure 102 may be formed to include greater than or equal to sixteen (16) of the tiers 108, such as greater than or equal to thirty-two (32) of the tiers 108, greater than or equal to sixty-four (64) of the tiers 108, greater than or equal to one hundred and twenty-eight (128) of the tiers 108, or greater than or equal to two hundred and fifty-six (256) of the tiers 108.

The insulative structures 104 of the tiers 108 of the stack structure 102 may individually be formed of and include insulative material, such as one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and MgOₓ), at least one dielectric nitride material (e.g., SiN_{y}), at least one dielectric oxynitride material (e.g., SiOₓN_{y}), and at least one dielectric carboxynitride material (e.g., SiOₓC_{z}N_{y}). In some embodiments, the insulative structures 104 of the tiers 108 of the stack structure 102 are individually formed of and include a dielectric oxide material, such as SiOₓ (e.g., SiO₂). The insulative structures 104 of the tiers 108 may individually be substantially homogeneous, or the insulative structure 104 of one or more (e.g., each) of the tiers 108 may individually be heterogeneous.

The conductive structures 106 of the tiers 108 of the stack structure 102 may individually be formed of and include conductive material, such as one or more of at least one conductively doped semiconductor material, at least one metal, at least one alloy, and at least one conductive metal-containing material (e.g., at last one conductive metal nitride, at least one conductive metal silicide, at least one conductive metal carbide, at least one conductive metal oxide). In some embodiments, each of the conductive structures 106 is formed of and includes W. Optionally, at least one liner material (e.g., at least one insulative liner material, at least one conductive liner material) may be formed around the conductive structures 106. The liner material may, for example, be formed of and include one or more of a metal (e.g., titanium, tantalum), an alloy, a metal nitride (e.g., tungsten nitride, titanium nitride, tantalum nitride), and a metal oxide (e.g., aluminum oxide). In some embodiments, the liner material comprises at least one conductive material employed as a seed material for the formation of the conductive structures 106. In some embodiments, the liner material comprises titanium nitride (TiNₓ, such as TiN). In further embodiments, the liner material further includes aluminum oxide (AlOₓ, such as Al₂O₃). As a non-limiting example, for each of the tiers 108 of the stack structure 102, AlOₓ (e.g., Al₂O₃) may be formed directly adjacent the corresponding insulative structures 104, TiNₓ(e.g., TiN) may be formed directly adjacent the AlOₓ, and W may be formed directly adjacent the TiNₓ. For clarity and ease of understanding the description, the liner material is not illustrated in FIG. 1A and FIG. 1B, but it will be understood that the liner material may be disposed around the conductive structures 106. The conductive structures 106 of the tiers 108 of the stack structure 102 may be formed through a so-called “replacement gate” or “gate last” processing wherein sacrificial material (e.g., dielectric nitride material, such as SiN_{y}) of a preliminary stack structure is selectively removed (e.g., using a wet etchant comprising phosphoric acid (H₃PO₄)) relative to insulative material of the insulative structures 104, and then the resulting voids are filled with conductive material to form the conductive structures 106.

As depicted in FIG. 1B and FIG. 1C, the stack structure 102 may be divided (e.g., segmented, partitioned) into blocks 134 separated from one another by filled slot structures 140 (e.g., filled slits, filled openings, filled trenches). The filled slot structures 140 may vertically extend (e.g., in the Z-direction) completely through the stack structure 102. Referring to FIG. 1C, the blocks 134 and the filled slot structures 140 of the stack structure 102 may horizontally extend in parallel in the X-direction. As used herein, the term “parallel” means substantially parallel. Horizontally neighboring blocks 134 of the stack structure 102 may be separated from one another in the Y-direction orthogonal to the X-direction by the filled slot structures 140. The filled slot structures 140 may also horizontally extend in parallel in the X-direction.

Each of the blocks 134 of the stack structure 102 may exhibit substantially the same geometric configuration (e.g., substantially the same dimensions and substantially the same shape) as each other of the blocks 134, or one or more of the blocks 134 may exhibit a different geometric configuration (e.g., one or more different dimensions and/or a different shape) than one or more other of the blocks 134. In addition, each pair of horizontally neighboring blocks 134 of the stack structure 102 may be horizontally separated from one another by substantially the same distance (e.g., corresponding to a width in the Y-direction of each of the filled slot structures 140) as each other pair of horizontally neighboring blocks 134 of the stack structure 102, or at least one pair of horizontally neighboring blocks 134 of the stack structure 102 may be horizontally separated from one another by a different distance than that separating at least one other pair of horizontally neighboring blocks 134 of the stack structure 102. In some embodiments, the blocks 134 of the stack structure 102 are substantially uniformly (e.g., substantially non-variably, substantially equally, substantially consistently) sized, shaped, and spaced relative to one another.

The filled slot structures 140 may be formed of and include insulative material. The insulative material may include at least one dielectric material, such as one or more of at least one dielectric oxide material (e.g., one or more of SiOₓ, phosphosilicate glass, borosilicate glass, borophosphosilicate glass, fluorosilicate glass, AlOₓ, HfOₓ, NbO₋ₓ₋, TiOₓ, ZrOₓ, TaOₓ, and MgOₓ), at least one dielectric nitride material (e.g., SiN_{y}), at least one dielectric oxynitride material (e.g., SiOₓN_{y}), and at least one dielectric carboxynitride material (e.g., SiOₓC_{z}N_{y}). In some embodiments, the filled slot structures 140 are formed of and include dielectric oxide material, such as SiOₓ (e.g., SiO₂).

Referring collectively to FIG. 1A through FIG. 1C, the stack structure 102 may include stadium structures 112 formed therein. The stadium structures 112 may be distributed throughout the stack structure 102. As shown in FIG. 1, the stack structure 102 may include rows of the stadium structures 112 extending in parallel in an X-direction, and columns of the stadium structures 112 extending in a Y-direction orthogonal to the X-direction. The rows of the stadium structures 112 may individually include some of the stadium structures 112 at least partially (e.g., substantially) aligned with one another in the Y-direction. The columns of the of the stadium structures 112 may individually include other of the stadium structures 112 at least partially (e.g., substantially) aligned with one another in the X-direction. Different rows of the stadium structures 112 may be positioned within horizontal areas of different blocks 134 of the stack structure 102 than one another. An individual block 134 of the stack structure 102 may include at least one row of the stadium structures 112 within a horizontal area thereof. In addition, the columns of the stadium structures 112 may individually include stadium structures 112 within different blocks 134 of the stack structure 102 than one another.

Referring to FIG. 1A, at least some (e.g., each) of the stadium structures 112 within an individual block 134 of the stack structure 102 may be positioned at different vertical elevations in the Z-direction than one another. For example, as depicted in FIG. 1A, an individual block 134 may include a first stadium structure 112A, and a second stadium structure 112B at a relatively lower vertical position (e.g., in the Z-direction) within the block 134 than the first stadium structure 112A. In addition, stadium structures 112 may be substantially uniformly (e.g., equally, evenly) horizontally spaced apart from one another. An individually block 134 of the stack structure 102 may include a desired quantity of the stadium structures 112 within a horizontal area thereof. For example, an individual block 134 of the stack structure 102 may include greater than two (2) of the stadium structures 112 (e.g., greater than or equal to three (3) of the stadium structures, greater than or equal to four (4) of the stadium structures, greater than or equal to five (5) of the stadium structures 112, greater than or equal to ten (10) of the stadium structures 112, greater than or equal to twenty-five (25) of the stadium structures 112, greater than or equal to fifty (50) of the stadium structures 112), or less than or equal to two (2) of the stadium structures 112 (e.g., only one (1) of the stadium structures 112). As another example, within an individual block 134, stadium structures 112 may be at least partially non-uniformly (e.g., non-equally, non-evenly) horizontally spaced, such that at least one of the stadium structures 112 is separated from at least two other of the stadium structures 112 horizontally neighboring (e.g., in the X-direction) the at least one stadium structures 112 by different (e.g., non-equal) distances. As an additional non-limiting example, within an individual block 134, vertical positions (e.g., in the Z-direction) of the stadium structures 112 may alternate between relatively deeper and relatively shallower vertical positions.

An individual stadium structure 112 may include opposing staircase structures 114, and a central region 118 horizontally interposed between (e.g., in the X-direction) the opposing staircase structures 114. The opposing staircase structures 114 of an individual stadium structure 112 may include a forward staircase structure 114A and a reverse staircase structure 114B. A phantom line extending from a top of the forward staircase structure 114A to a bottom of the forward staircase structure 114A may have a positive slope, and another phantom line extending from a top of the reverse staircase structure 114B to a bottom of the reverse staircase structure 114B may have a negative slope. In additional embodiments, one or more of the stadium structures 112 may individually exhibit a different configuration than that depicted in FIG. 1A. As a non-limiting example, an individual stadium structure 112 may be modified to include a forward staircase structure 114A but not a reverse staircase structure 114B (e.g., the reverse staircase structure 114B may be absent), or an individual stadium structure 112 may be modified to include a reverse staircase structure 114B but not a forward staircase structure 114A (e.g., the forward staircase structure 114A may be absent). In such embodiments, the central region 118 horizontally neighbors a bottom of the forward staircase structure 114A (e.g., if the reverse staircase structure 114B is absent), or horizontally neighbors a bottom of the reverse staircase structure 114B (e.g., if the forward staircase structure 114A is absent).

The opposing staircase structures 114 (e.g., the forward staircase structure 114A and the reverse staircase structure 114B) of an individual stadium structure 112 may individually include steps 116 defined by edges (e.g., horizontal ends) of the tiers 108 of the stack structure 102 within a horizontal area of an individual block 134 of the stack structure 102. For the opposing staircase structures 114 of an individual stadium structure 112, each step 116 of the forward staircase structure 114A may have a counterpart step 116 within the reverse staircase structure 114B having substantially the same geometric configuration (e.g., shape, dimensions), vertical position (e.g., in the Z-direction), and horizontal distance (e.g., in the X-direction) from a horizontal center (e.g., in the X-direction) of the central region 118 of the stadium structure 112. In additional embodiments, at least one step 116 of the forward staircase structure 114A does not have a counterpart step 116 within the reverse staircase structure 114B having substantially the same geometric configuration (e.g., shape, dimensions), vertical position (e.g., in the Z-direction), and/or horizontal distance (e.g., in the X-direction) from horizontal center (e.g., in the X-direction) of the central region 118 of the stadium structure 112; and/or at least one step 116 of the reverse staircase structure 114B does not have a counterpart step 116 within the forward staircase structure 114A having substantially the same geometric configuration (e.g., shape, dimensions), vertical position (e.g., in the Z-direction), and/or horizontal distance (e.g., in the X-direction) from horizontal center (e.g., in the X-direction) of the central region 118 of the stadium structure 112.

Each of the stadium structures 112 within an individual block 134 of the stack structure 102 may individually include a desired quantity of steps 116. Each of the stadium structures 112 may include substantially the same quantity of steps 116 as each other of the stadium structures 112, or at least one of the stadium structures 112 may include a different quantity of steps 116 than at least one other of the stadium structures 112. In some embodiments, at least one of the stadium structures 112 includes a different (e.g., greater, lower) quantity of steps 116 than at least one other of the stadium structures 112. As shown in FIG. 1A, in some embodiments, the steps 116 of each of the stadium structures 112 are arranged in order, such that steps 116 directly horizontally adjacent (e.g., in the X-direction) one another correspond to tiers 108 of the stack structure 102 directly vertically adjacent (e.g., in the Z-direction) one another. In additional embodiments, the steps 116 of at least one of the stadium structures 112 are arranged out of order, such that at least some steps 116 of the stadium structure 112 directly horizontally adjacent (e.g., in the X-direction) one another correspond to tiers 108 of the stack structure 102 not directly vertically adjacent (e.g., in the Z-direction) one another. In some embodiments, an individual stadium structure 112 may be horizontally continuous (e.g., in the Y-direction) such that there is no horizontal region (e.g., in the Y-direction) separating stadium structures 112.

With continued reference to FIG. 1A, for an individual stadium structure 112, the central region 118 thereof may horizontally intervene (e.g., in the X-direction) between and separate the forward staircase structure 114A thereof from the reverse staircase structure 114B thereof. The central region 118 may horizontally neighbor a vertically lowermost step 116 of the forward staircase structure 114A, and may also horizontally neighbor a vertically lowermost step 116 of the reverse staircase structure 114B. The central region 118 of an individual stadium structure 112 may have any desired horizontal dimensions. In addition, within an individual block 134 of the stack structure 102, the central region 118 of each of the stadium structures 112 may have substantially the same horizontal dimensions as the central region 118 of each other of the stadium structures 112, or the central region 118 of at least one of the stadium structures 112 may have different horizontal dimensions than the central region 118 of at least one other of the stadium structures 112.

Referring collectively to FIG. 1A and FIG. 1B, each stadium structure 112 (including the forward staircase structure 114A, the reverse staircase structure 114B, and the central region 118 thereof) within an individual block 134 of the stack structure 102 may individually partially define boundaries (e.g., horizontal boundaries, vertical boundaries) of a filled trench 120 vertically extending (e.g., in the Z-direction) partially through the stack structure 102. The portions of the stack structure 102 horizontally neighboring an individual stadium structure 112 may also partially define the boundaries of the filled trench 120 associated with the stadium structure 112. The filled trench 120 may vertically extend only through tiers 108 of the stack structure 102 defining the forward staircase structure 114A and the reverse staircase structure 114B of the stadium structure 112; or may also vertically extend through additional tiers 108 of the stack structure 102 not defining the forward staircase structure 114A and the reverse staircase structure 114B of the stadium structure 112, such as additional tiers 108 of the stack structure 102 vertically overlying the stadium structure 112. Edges of the additional tiers 108 of the stack structure 102 may, for example, define one or more additional stadium structures vertically overlying and horizontally offset from the stadium structure 112.

The filled trenches 120 may individually include multiple (e.g., more than one) dielectric materials. For example, as shown in FIG. 1B, an individual filled trench 120 may include a first dielectric material 126 (e.g., a dielectric liner material), a second dielectric material 128 (e.g., an additional dielectric liner material), and a third dielectric material 130 (e.g., a dielectric fill material). For an individual filled trench 120 within a horizontal area of an individual block 134 of the stack structure 102, the first dielectric material 126 may be formed on or over surfaces (e.g., horizontally extending surfaces, vertically extending surfaces) of the block 134, the second dielectric material 128 may be formed on or over the first dielectric material 126, and the third dielectric material 130 may be formed on or over the second dielectric material 128. As depicted in FIG. 1B, one or more (e.g., each) of the first dielectric material 126, the second dielectric material 128, and the third dielectric material 130 may also be formed to extend beyond boundaries (e.g., horizontal boundaries, vertical boundaries) of the filled trenches 120. For example, first dielectric material 126, the second dielectric material 128, and the third dielectric material 130 may also be formed to extend over uppermost surfaces of an individual block 134 of the stack structure 102. In additional embodiments, the first dielectric material 126 and/or the second dielectric material 128 may be omitted (e.g., absent). In some embodiments, the first dielectric material 126 is formed of and includes SiOₓ (e.g., SiO₂), the second dielectric material 128 is formed of and includes SiN_{y} (e.g., Si₂N₄), and the third dielectric material 130 is formed of and includes additional SiOₓ (e.g., additional SiO₂).

With reference to FIG. 1A and FIG. 1C, individual blocks 134 of the stack structure 102 may further include crest regions 122 (e.g., elevated regions) and bridge regions 124 (e.g., additional elevated regions). The crest regions 122 may horizontally alternate with the stadium structures 112 in the X-direction. The bridge regions 124 may horizontally neighbor opposing sides of individual stadium structures 112 in the Y-direction, and may horizontally extend from and between crest regions 122 horizontally neighboring one another in the X-direction.

The crest regions 122 of an individual block 134 of the stack structure 102 may intervene between and separate stadium structures 112 horizontally neighboring one another in the X-direction. For example, one of the crest regions 122 may intervene between and separate the first stadium structure 112A and the second stadium structure 112B; an additional one of the crest regions 122 may intervene between and separate the second stadium structure 112B and a third stadium structure; and a further one of the crest regions 122 may intervene between and separate the third stadium structure and a fourth stadium structure. A vertical height of the crest regions 122 in the Z-direction may be substantially equal to a maximum vertical height of the block 134 in the Z-direction; and a horizontal width of the crest regions 122 in the Y-direction may be substantially equal to a maximum horizontal width of the block 134 in the Y-direction. In addition, each of the crest regions 122 may individually exhibit a desired horizontal length in the X-direction. Each of the crest regions 122 of an individual block 134 of the stack structure 102 may exhibit substantially the same horizontal length in the X-direction as each other of the crest regions 122 of the block 134; or at least one of the crest regions 122 of the block 134 may exhibit a different horizontal length in the X-direction than at least one other of the crest regions 122 of the block 134.

With reference to FIG. 1B and FIG. 1C, the bridge regions 124 of an individual block 134 of the stack structure 102 may intervene between and separate the stadium structures 112 of the block 134 from the filled slot structures 140 horizontally neighboring the block 134 in the Y-direction. For example, for each stadium structure 112 within an individual block 134 of the stack structure 102, a first bridge region 124A may be horizontally interposed in the Y-direction between a first side of the stadium structure 112 and a first of the filled slot structures 140 horizontally neighboring the block 134; and a second bridge region 124B may be horizontally interposed in the Y-direction between a second side of the stadium structure 112 and a second of the filled slot structures 140 horizontally neighboring the block 134. The first bridge region 124A and the second bridge region 124B may horizontally extend in parallel in the X-direction. In addition, the first bridge region 124A and the second bridge region 124B may each horizontally extend from and between crest regions 122 of the block 134 horizontally neighboring one another in the X-direction. The bridge regions 124 of the block 134 may be integral and continuous with the crest regions 122 of the block 134. Upper boundaries (e.g., upper surfaces in the Z-direction) of the bridge regions 124 may be substantially coplanar with upper boundaries of the crest regions 122. A vertical height of the bridge regions 124 in the Z-direction may be substantially equal to a maximum vertical height of the block 134 in the Z-direction. In addition, each of the bridge regions 124 (including each first bridge region 124A and each second bridge region 124B) may individually exhibit a desired horizontal width in the Y-direction and a desired horizontal length in the X-direction. Each of the bridge regions 124 of the block 134 may exhibit substantially the same horizontal length in the X-direction as each other of the bridge regions 124 of the block 134; or at least one of the bridge regions 124 of the block 134 may exhibit a different horizontal length in the X-direction than at least one other of the bridge regions 124 of the block 134. In addition, each of the bridge regions 124 of the block 134 may exhibit substantially the same horizontal width in the Y-direction as each other of the bridge regions 124 of the block 134; or at least one of the bridge regions 124 of the block 134 may exhibit a different horizontal width in the Y-direction than at least one other of the bridge regions 124 of the block 134.

For an individual block 134 of the stack structure 102, the bridge regions 124 thereof horizontally extend around the filled trenches 120 of the block 134. As described in further detail below, some of the bridge regions 124 of the block 134 may be employed to form continuous conductive paths extending from and between horizontally neighboring crest regions 122 of the block 134. As also described in further detail below, at least the bridge regions 124 (e.g., the first bridge region 124A and the second bridge region 124B) horizontally neighboring the first stadium structure 112A in the Y-direction may be segmented to disrupt (e.g., break) at least a portion of the continuous conductive paths extending from and between the crest regions 122 horizontally neighboring the first stadium structure 112A in the X-direction.

Referring collectively to FIG. 1A-FIG. 1C, within horizontal areas of the blocks 134 of the stack structure 102, the microelectronic device structure 100 further includes additional filled slot structures 110 and at least one further filled slot structure 111. An individual block 134 of the stack structure 102 may include a group of the additional filled slot structures 110 within a horizontal area thereof, such as a first additional filled slot structure 110A, a second additional filled slot structure 110B, and a third additional filled slot structure 110C. The additional filled slot structures 110 horizontally extend in the X-direction and vertically extend in the Z-direction partially (e.g., less than completely) through at least some (e.g., each) of the blocks 134 of the stack structure 102. The further filled slot structure 111 horizontally extends in the Y-direction and vertically extends in the Z-direction partially through at least some (e.g., each) of the blocks 134 of the stack structure 102. The further filled slot structure 111 may be horizontally offset, in the X-direction, from each of the stadium structures 112. As shown in FIG. 1C, the additional filled slot structures 110 partially define and horizontally separate (e.g., in the Y-direction) sub-blocks 144 of individual blocks 134 of the stack structure 102. In addition, as shown in FIG. 1C, the further filled slot structure 111 may segment portions of the crest regions 122 of individual blocks 134 of the stack structure 102. As described in further detail below, within a horizontal area of an individual block 134, the further filled slot structure 111 may intersect at least one of the additional filled slot structures 110 (e.g., the second additional filled slot structure 110B) of a group of the additional filled slot structures 110 within the horizontal area of the block 134, and may not intersect (e.g., may be completely horizontally offset from in the X-direction) at least one other of the additional filled slot structures 110 (e.g., the first additional filled slot structure 110A, the third additional filled slot structure 110C) of the group of the additional filled slot structures 110.

The additional filled slot structures 110 and the further filled slot structure 111 may comprise slots (e.g., openings, trenches, slits) in the stack structure 102 filled with at least one dielectric material. A material composition of the dielectric material of the additional filled slot structures 110 and the further filled slot structure 111 may be substantially the same as a material composition of the dielectric material of the filled slot structures 140; or the material composition of the dielectric material of the additional filled slot structures 110 and/or the further filled slot structure 111 may be different than the material composition of the dielectric material of the filled slot structures 140. In some embodiments, the additional filled slot structures 110 and the further filled slot structure 111 are individually formed of and include at least one dielectric oxide material (e.g., SiOₓ, such as SiO₂). In additional embodiments, the additional filled slot structures 110 and/or the further filled slot structure 111 are formed of and include at least one dielectric nitride material (e.g., SiN_{y}, such as Si₃N₄).

Within the horizontal area of an individual block 134 of the stack structure 102, a group of the additional filled slot structures 110 may be formed to horizontally extend in the X-direction into a horizontal area of the first stadium structure 112A of the block 134. The additional filled slot structures 110 of the group may, for example, individually horizontally extend in the X-direction through a crest region 122 of the block 134 horizontally neighboring the first stadium structure 112A and partially or completely through a horizontal area the first stadium structure 112A. Each of the additional filled slot structures 110 of the group may vertically terminate at or within vertical boundaries of the relatively vertically higher tiers 108A of the stack structure 102. In some embodiments, some of the additional filled slot structures 110 (e.g., the first additional filled slot structure 110A, the third additional filled slot structure 110C) horizontally terminate (e.g., horizontally end) in the X-direction at or above a relatively lowest step 116 of the one of the opposing staircase structures 114 (e.g., the reverse staircase structure 114B) within vertical boundaries (e.g., in the Z-direction) defined by the relatively vertically higher tiers 108A of the stack structure 102. Within an individual block 134, horizontal ends of the relatively lowest tier 108 of the relatively vertically higher tiers 108A of the stack structure 102 may define the relatively lowest step 116 of the one of the opposing staircase structures 114 (e.g., the reverse staircase structure 114B). One of more other of the additional filled slot structures 110 (e.g., the second additional filled slot structure 110B) may horizontally terminate (e.g., horizontally end) in the X-direction at or within one of the crest regions 122 horizontally neighboring the first stadium structure 112A (e.g., horizontally adjacent the forward staircase structure 114A thereof). For example, the second additional filled slot structure 110B may horizontally extend in the X-direction completely across the first stadium structure 112A, whereas the first additional filled slot structure 110A and the third additional filled slot structure 110C may horizontally terminate in the X-direction within the first stadium structure 112A.

An individual block 134 of the stack structure 102 may include greater than or equal to one (1) of the additional filled slot structures 110 within a horizontal area thereof, such as greater than or equal to two (2) of the additional filled slot structures 110, or greater than or equal to three (3) of the additional filled slot structures 110. In some embodiments, at least some (e.g., each) of the blocks 134 of the stack structure 102 individually include three (3) of the additional filled slot structures 110 within a horizontal area thereof (such as the first additional filled slot structure 110A, the second additional filled slot structure 110B, and the third additional filled slot structure 110C) within a horizontal area thereof. The second additional filled slot structure 110B may be horizontally interposed between the first additional filled slot structure 110A and the third additional filled slot structure 110C in the Y-direction.

For an individual block 134 of the stack structure 102, a group of the additional filled slot structures 110 may sub-divide the block 134 into at least two (2) sub-blocks 144. For example, as shown in FIG. 1C, if an individual block 134 includes three (3) of the additional filled slot structures 110 (e.g., the first additional filled slot structure 110A, the second additional filled slot structure 110B, and the third additional filled slot structure 110C) within a horizontal area thereof, the additional filled slot structures 110 may sub-divide the block 134 into four (4) sub-blocks 144, such as a first sub-block 144A, a second sub-block 144B, a third sub-block 144C, and a fourth sub-block 144D.

Within an individual block 134 of the stack structure 102, the conductive structures 106 of one or more of the relatively vertically higher tier(s) 108A segmented by the additional filled slot structures 110 may be used as upper select gate structures 156 (e.g., first select gate structures, drain side select gate (SGD) structures) (FIG. 1B) of the block 134. The upper select gate structures 156 may be employed for upper select transistors (e.g., drain side select transistors) of the block 134. In some embodiments, within an individual block 134 of the stack structure 102, the conductive structures 106 of each of less than or equal to eight (8) relatively higher tier(s) 108A (e.g., from one (1) relatively vertically higher tier 108A to eight (8) relatively vertically higher tiers 108A) of the stack structure 102 are employed to form the upper select gate structures 156 for the block 134. Moreover, within an individual block 134 of the stack structure 102, the conductive structures 106 of at least a vertically lowest tier 108 may be employed for at least one lower select gate structure (e.g., at least one second select gate structure, at least one source side select gate (SGS) structure) of the block 134, as described in further detail below.

Referring collectively to FIG. 1B and FIG. 1C, in some embodiments, for an individual block 134, an individual vertically higher tier 108A includes four (4) upper select gate structures 156. Each of the upper select gate structures 156 of the vertically higher tier 108A of the block 134 may be positioned within a different one of the four (4) sub-blocks 144 (e.g., the first sub-block 144A, the second sub-block 144B, the third sub-block 144C, the fourth sub-block 144D) of the block 134 than each other of the upper select gate structures. The additional filled slot structures 110 within a horizontal area of the block 134 may horizontally intervene between (e.g., in the Y-direction) and separate the upper select gate structures 156 of the individual vertically higher tier 108A.

Referring collectively to FIG. 1A-FIG. 1C, within horizontal areas of the stadium structures 112, the microelectronic device structure 100 further includes contact structures 136. The contact structures 136 may vertically extend through the filled trenches 120 to at least some of the steps 116 of an individual stadium structure 112. A lower vertical boundary (e.g., a lower surface) of an individual contact structure 136 may physically contact (e.g., land on) the conductive structure 106 of an individual tier 108 of the stack structure 102 at an individual step 116 of an individual stadium structure 112. In addition, an upper vertical boundary (e.g., an upper surface) of an individual contact structure 136 may be substantially coplanar with an upper vertical boundary (e.g., an upper surface) of an individual filled trench (e.g., an upper vertical boundary of the third dielectric material 130 thereof).

The contact structures 136 may include first contact structures 136A and second contact structures 136B. Within a horizontal area of an individual block 134, the first contact structures 136A may be positioned within a horizontal area of the first stadium structure 112A of the block 134, and at least some of the second contact structures 136B may be positioned within a horizontal areas of the additional, relatively lower stadium structures 112 (e.g., the second stadium structure 112B) of the block 134. The first contact structures 136A may vertically extend to and terminate at relatively vertically higher tiers 108A of the stack structure 102, and may be coupled to the upper select gate structures 156 within the sub-blocks 144 of the block 134. In addition, the second contact structures 136B may vertically extend to and terminate at relatively vertically lower tiers 108B of the stack structure 102, and may be coupled to local access line structures of the block 134 defined by portions of the conductive structures 106 of the relatively vertically lower tiers 108B of the stack structure 102.

For an individual block 134, multiple (e.g., more than one) first contact structures 136A may vertically extend to portions of an individual vertically higher tier 108A at a step 116 of the first stadium structure 112A. In FIG. 1C, dashed lines are illustrated to depict the dimensions and arrangement of some of the steps 116 of the first stadium structure 112A. As shown in FIG. 1C, an individual step 116 of the first stadium structure 112A defined by a horizontal end of an individual vertically higher tier 108A may include multiple first contact structures 136A within a horizontal area thereof. Each first contact structure 136A of a group of the first contact structures 136A within a horizontal area of an individual step 116 of the first stadium structure 112A may be positioned within different sub-blocks 144 of the block 134 than one another. At least some first contact structures 136A of a group of the first contact structures 136A within a horizontal area of an individual sub-block 144 of the block 134 may be horizontally aligned with one another in the Y-direction, as described in further detail below.

Referring collectively to FIG. 1B and FIG. 1C, the sub-blocks 144 of an individual block 134 of the stack structure 102 may individually include at least one row of the first contact structures 136A operatively associated with the upper select gate structures 156 thereof. In some embodiments, the first sub-block 144A, the second sub-block 144B, the third sub-block 144C, and the fourth sub-block 144D of an individual block 134 individually include one (1) row of the first contact structures 136A operatively associated with the upper select gate structures 156 thereof. The upper select gate structures 156 of the first sub-block 144A may be coupled to a first row of the first contact structures 136A positioned within a horizontal area of the forward staircase structure 114A of the first stadium structure 112A. The upper select gate structures 156 of the second sub-block 144B may be coupled to a second row of the first contact structures 136A positioned within a horizontal area of the reverse staircase structure 114B of the first stadium structure 112A. The upper select gate structures 156 of the third sub-block 144C may be coupled to a third row of the first contact structures 136A positioned within a horizontal area of the reverse staircase structure 114B of the first stadium structure 112A. The upper select gate structures 156 of the fourth sub-block 144D may be coupled to a fourth row of the first contact structures 136A positioned within a horizontal area of the forward staircase structure 114A of the first stadium structure 112A. As shown in FIG. 1C, in some embodiments, an arrangement the third row of the first contact structures 136A and the fourth row of the first contact structures 136A within the block 134 mirrors an arrangement of the first row of the first contact structures 136A and the second row of the first contact structures 136A about the second additional filled slot structure 110B.

Within an individual block 134, for an individual group (e.g., row) of the first contact structures 136A within a horizontal area of the reverse staircase structure 114B of the first stadium structure 112A and operatively associated with an individual sub-block 144 (e.g., the second sub-block 144B, the third sub-block 144C), at least some (e.g., all) of the first contact structures 136A of the group may be substantially horizontally centered in the Y-direction within the sub-block 144. For example, a horizontal center in the Y-direction of a second row of the first contact structures 136A operatively associated with the second sub-block 144B may be substantially aligned with a horizontal center in the Y-direction of the second sub-block 144B. As another example, a horizontal center in the Y-direction of a third row of the first contact structures 136A operatively associated with the third sub-block 144C may be substantially aligned with a horizontal center in the Y-direction of the third sub-block 144C. In additional embodiments, for at least one group (e.g., row) of the first contact structures 136A positioned within the horizontal area of the reverse staircase structure 114B of the first stadium structure 112A and operatively associated with an individual sub-block 144 (e.g., the second sub-block 144B, the third sub-block 144C), at least some (e.g., all) of the first contact structures 136A of the group are offset in the Y-direction from a horizontal center in the Y-direction of the sub-block 144.

Within an individual block 134, for an individual group (e.g., row) of the first contact structures 136A within a horizontal area of the forward staircase structure 114A of the first stadium structure 112A and operatively associated with an individual sub-block 144 (e.g., the first sub-block 144A, the fourth sub-block 144D), at least some (e.g., all) of the first contact structures 136A are substantially horizontally aligned in the Y-direction with an individual additional filled slot structure 110 (e.g., the first filled slot structure 110A, the third filled slot structure 110C) horizontally interposed in the Y-direction between neighboring sub-blocks 144. For example, a horizontal center in the Y-direction of a first row of the first contact structures 136A operatively associated with the first sub-block 144A may be substantially aligned with a horizontal center in the Y-direction of the first additional filled slot structure 110A. As another example, a horizontal center in the Y-direction of a fourth row of the first contact structures 136A operatively associated with the fourth sub-block 144D may be substantially aligned with a horizontal center in the Y-direction of the third additional filled slot structure 110C. In additional embodiments, for at least one group (e.g., row) of the first contact structures 136A positioned within the horizontal area of the forward staircase structure 114A of the first stadium structure 112A and operatively associated with an individual sub-block 144 (e.g., the first sub-block 144A, the fourth sub-block 144D) of an individual block 134, at least some (e.g., all) of the first contact structures 136A of the group are offset in the Y-direction from a horizontal center in the Y-direction of the additional filled slot structure 110 most horizontally proximate thereto.

In additional embodiments wherein an individual block 134 is subdivided into a different number of sub-blocks 144, the block 134 may include a different quantity of rows of the first contact structures 136A equal to the different quantity of sub-blocks 144. In other embodiments, the quantity of rows of first contact structures 136A in the block 134 are not equal to the quantity of sub-blocks 144 in the block 134. In various embodiments, for each sub-block 144 of an individual block 134 of the stack structure 102, the first contact structures 136A operatively associated with the sub-block 144 may be provided at desired horizontal positions (e.g., in the X-direction and the Y-direction) on the steps 116 of the first stadium structure 112A.

Referring to FIG. 1C, in some embodiments, for an individual the block 134 of the stack structure 102, the second contact structures 136B contact at least some of the steps 116 of one or more other of the stadium structures 112 vertically underlying the first stadium structure 112A, such as at least some of the steps 116 of the second stadium structure 112B. In some embodiments, a group (e.g., row) of the second contact structures 136B is substantially horizontally centered in the Y-direction on the steps 116 of the second stadium structure 112B. For example, a horizontal center in the Y-direction of the second contact structures 136B of the group may be substantially aligned with horizontal centers in the Y-direction of the step 116 of the second stadium structure 112B. In addition, a horizontal center in the X-direction of an individual second contact structure 136B may be substantially aligned with a horizontal center in the X-direction of the step 116 that the second contact structure 136B contacts. In additional embodiments, for an individual block 134 of the stack structure 102, one or more of the second contact structures 136B are horizontally offset in the Y-direction from a horizontal center in the Y-direction of the step 116 in contact therewith, and/or are horizontally offset in the X-direction from a horizontal center in the X-direction of the step 116 in contact therewith.

The blocks 134 of the stack structure 102 may individually include a desired distribution of the second contact structures 136B within horizontal areas of the stadium structures 112 (e.g., the second stadium structure 112B) thereof. For example, for an individual block 134 of the stack structure 102, the second stadium structure 112B thereof may include at least one (1) row of the second contact structures 136B. Each row of the second contact structures 136B may horizontally extend in the X-direction, and may individually include a portion of the second contact structures 136B provided within a horizontal area of the block 134. In some embodiments, at least one of the opposing staircase structures 114 (e.g., the reverse staircase structure 114B and/or the forward staircase structure 114A) of the second stadium structure 112B includes a single (e.g., only one (1)) row of the second contact structures 136B within a horizontal area thereof. A horizontal centerline of the single row of the second contact structures 136B may be substantially aligned with a horizontal centerline of the block 134 (as depicted in FIG. 1C), or the horizontal centerline of the single row of the second contact structures 136B may be horizontally offset (e.g., in the Y-direction) from the horizontal centerline of the block 134. In additional embodiments, at least one of the opposing staircase structures 114 (e.g., the reverse staircase structure 114B and/or the forward staircase structure 114A) of the second stadium structure 112B includes more than one (1) row of the second contact structures 136B within a horizontal area thereof, such as at least two (2) rows of the second contact structures 136B, at least three (3) rows of the second contact structures 136B, or at least four (4) rows of the second contact structures 136B. In further embodiments, the second contact structure 136B are provided on steps 116 of the second stadium structure 112B in a different arrangement than in one or more of rows horizontally extending in the X-direction. For example, the second contact structures 136B may be arranged in a diagonal pattern extending substantially linearly in the X-direction and the Y-direction on steps 116 of the second stadium structure 112B, or may be arranged in an at least partially non-linear pattern (e.g., a curved pattern, a zigzag pattern, a random pattern, an irregular pattern) on steps 116 of the second stadium structure 112B.

The contact structures 136, including the first contact structures 136A and the second contact structures 136B, may individually exhibit a desired horizontal cross-sectional shape. In some embodiments, each of the contact structures 136 exhibits a substantially circular horizontal cross-sectional shape. In additional embodiments, one or more (e.g., each) of the contact structures 136 exhibits a non-circular cross-sectional shape, such as one more of an oblong cross-sectional shape, an elliptical cross-sectional shape, a square cross-sectional shape, a rectangular cross-sectional shape, a tear drop cross-sectional shape, a semicircular cross-sectional shape, a tombstone cross-sectional shape, a crescent cross-sectional shape, a triangular cross-sectional shape, a kite cross-sectional shape, and an irregular cross-sectional shape. In addition, each of the contact structures 136 may exhibit substantially the same horizontal cross-sectional dimensions (e.g., substantially the same horizontal diameter), or at least one of the contact structures 136 may be formed to exhibit one or more different horizontal cross-sectional dimensions (e.g., a different horizontal diameter) than at least one other of the contact structures 136. In some embodiments, all of the contact structures 136 are formed to exhibit substantially the same horizontal cross-sectional dimensions.

The contact structures 136, including the first contact structures 136A and the second contact structures 136B, may individually be formed of and include conductive material. As a non-limiting example, the contact structures 136 may individually be formed of and include one or more of at least one metal, at least one alloy, and at least one conductive metal-containing material (e.g., a conductive metal nitride, a conductive metal silicide, a conductive metal carbide, a conductive metal oxide). A material composition of the contact structures 136 may be substantially the same as a material composition of the conductive structures 106 of the tiers 108 of the stack structure 102, or the material composition of the contact structures 136 may be different than the material composition of the conductive structures 106 of the tiers 108 of the stack structure 102. In some embodiments, the contact structures 136 are individually formed of and include W. The contact structures 136 may individually be homogeneous, or the contact structures 136 may individually be heterogeneous.

Referring collectively to FIGS. 1A and 1C, within horizontal areas of the stadium structures 112, the microelectronic device structure 100 may further include support structures 146 (e.g., additional contact structures). The support structures 146 vertically extend (e.g., in the Z-direction) through the filled trenches 120 (including the third dielectric material 130, the second dielectric material 128, and the first dielectric material 126 thereof) and through portions of the stack structure 102 vertically underlying and within horizontal areas of the filled trenches 120. Configurations and arrangements of the support structures 146 may be selected to mitigate (e.g., prevent) undesirable tier damage (e.g., tier collapse) during so-called “replacement gate” processes to form the conductive structures 106 of the tiers 108 of the stack structure 102.

As shown in FIG. 1C, within a horizontal area of the first stadium structure 112A of an individual block 134 of the stack structure 102, at least one array of the support structures 146 may include rows of the support structures 146 extending in the X-direction, and columns of the support structures 146 extending in the Y-direction. The array of the support structures 146 may, for example, include at least two (2) rows (e.g., at least three (3) rows) of the support structures 146 extending in parallel the X-direction. In some embodiments, the array of the support structures 146 includes at least three (3) rows of the support structures 146. The support structures 146 within in each of the rows of the support structures 146 may individually have substantially the same configuration (e.g., shape, dimensions) and arrangement as each of the support structures 146 within each other of the rows of the support structures 146; or at least one the support structures 146 within at least one of the rows of the support structures 146 may have one or more of a different configuration (e.g., a different shape, at least one different dimension) and a different arrangement than at least one of the support structures 146 within at least one other of the rows of the support structures 146. In addition, a group of the support structures 146 of the array within horizontal areas of steps 116 of the first stadium structure 112A defined by the vertically higher tiers 108A may have a different arrangement than an additional group of the support structures 146 of the array within horizontal areas of steps 116 of the first stadium structure 112A defined by the vertically lower tiers 108B. Furthermore, a group of the support structures 146 within a horizontal area of the forward staircase structure 114A of the first stadium structure 112A may have a different arrangement than another group of the support structures 146 within a horizontal area of the reverse staircase structure 114B of the first stadium structure 112A.

Within a horizontal area of the first stadium structure 112A of an individual block 134 of the stack structure 102, an arrangement of the support structures 146 may at least partially depend on an arrangement of the contact structures 136 (e.g., at least that first contact structures 136A). As shown in FIG. 1C, rows of the support structures 146 may horizontally overlap rows of the first contact structures 136A in the Y-direction, and the support structures 146 of an individual row of the support structures 146 may horizontally alternate, in the X-direction, with the first contact structures 136A of a horizontally overlapping row of the first contact structures 136A. Horizontal centers of the support structures 146 of an individual row of the support structures 146 may be substantially horizontally aligned, in the Y-direction, with horizontal centers of the first contact structures 136A of a horizontally overlapping row of the first contact structures 136A. Similarly, horizontal centers of the support structures 146 of an individual row of the support structures 146 may be substantially horizontally aligned, in the Y-direction, with horizontal centers of the second contact structures 136B of a horizontally overlapping row of the second contact structures 136B.

The support structures 146 may individually be formed of and include one or more of conductive material, insulative material, and semiconductive material. In some embodiments, the support structures 146 are individually formed of and include conductive material, such as one or more of at least one metal (e.g., W, Ti, Mo, Nb, V, Hf, Ta, Cr, Zr, Fe, Ru, Os, Co, Rh, Ir, Ni, Pa, Pt, Cu, Ag, Au, Al), at least one alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a Mg-based alloy, a Ti-based alloy, a steel, a low-carbon steel, a stainless steel), at least one conductive metal-containing material (e.g., a conductive metal nitride, a conductive metal silicide, a conductive metal carbide, a conductive metal oxide), and at least one conductively-doped semiconductor material (e.g., conductively-doped Si, conductively-doped Ge, conductively-doped SiGe). In additional embodiments, one or more of the support structures 146 are formed of and include one or more of insulative structure and semiconductive material. The support structures 146 may individually be formed of and include a single (e.g., only one) material, or may individually be formed of and including multiple (e.g., more than one) materials. By way of non-limiting example, the support structures 146 may individually be formed to include a conductive core material surrounded by an insulative liner material. The insulative liner material may substantially surround (e.g., substantially horizontally and vertically cover) sidewalls of the conductive core material of the support structures 146. The insulative liner material may be horizontally interposed between the conductive core material of the support structures 146 and the tiers 108 (including the conductive structures 106 and the insulative structures 104 thereof) of the stack structure 102.

As depicted in FIG. 1A and FIG. 1B, the microelectronic device structure 100 may further include conductive routing structures 132 vertically underlying the stack structure, and deep contact structures 138 in electrical communication with the conductive routing structures 132 and vertically extending (e.g., in the Z-direction) through the stack structure 102. At least some of the conductive routing structures 132 may be coupled to control logic circuitry (e.g., string drive circuitry) of a control logic structure (e.g., a control unit) vertically underlying the stack structure 102. The deep contact structures 138 may be positioned within horizontal areas of the crest regions 122 of the blocks 134 of the stack structure 102. As described in further detail below, for individual blocks 134 of the stack structure 102, the conductive routing structures 132 may be coupled to at least some of the conductive structures 106 of the stack structure 102 by way of the deep contact structures 138. The conductive routing structures 132 and the deep contact structures 138 may individually be formed of and including conductive material, such as one or more of the conductive materials previously described herein in relation to the contact structures 136.

Referring collectively to FIG. 1A through FIG. 1C, the microelectronic device structure 100 further includes select line routing structures 148 in electrical communication with the first contact structures 136A and the deep contact structures 138 vertically extending (e.g., in the Z-direction) through the stack structure 102. The select line routing structures 148 may vertically overlie an upper boundary of the stack structure 102. Within a horizontal area of an individual block 134, some portions of select line routing structures 148 may individually horizontally extend (e.g., in the X-direction) from a deep contact structure 138 horizontally positioned within a crest region 122 of the block 134 to one or more (e.g., each of a group, each of a row) of the first contact structures 136A within a horizontal area of the first stadium structure 112A of the block 134. Additionally, some portions of the select line routing structures 148 may individually horizontally extend (e.g., in the Y-direction) from and between additional portions of the select line routing structures 148, and/or from other portions of the select line routing structures 148 to one or more of the first contact structures 136A within a horizontal area of the first stadium structure 112A of the block 134. In this manner, the select line routing structures 148 (and the first contact structures 136A coupled thereto) may electrically connect the upper select gate structures 156 within the sub-blocks 144 of the block 134 to at least some of the deep contact structures 138. In addition, as shown in FIG. 1C, some the select line routing structures 148 may be employed as jumper structures extending over the additional filled slot structures 110 and/or the further filled slot structure 111. For example, for an individual block 134, one or more of the select line routing structures 148 horizontally extend in the Y-direction over the second additional filled slot structure 110B to facilitate electrical communication between different first contact structures 136A horizontally separated from one another by the second additional filled slot structure 110B. As another example, for an individual block 134, one or more of the select line routing structures 148 horizontally extend in the X-direction over the further filled slot structure 111 to facilitate electrical communication between one or more of the first contact structures 136A and one or more of the deep contact structures 138. One or more of select line routing structures 148 may intersect one or more other of the select line routing structures 148, thereby forming one or more select line routing junctions 148A. In some embodiments, at least some (e.g., each) of the select line routing structures 148 individually extend in a substantially linear path in the X-direction or the Y-direction.

As shown in FIG. 1C, portions of select line routing structures 148 may individually be sized, shaped, and configured to electrically connect (e.g., gang) multiple first contact structures 136A (and, hence, multiple upper select gate structures 156) operatively associated with the same sub-block 144 (e.g., the first sub-block 144A, the second sub-block 144B, the third sub-block 144C, the fourth sub-block 144D) or within different sub-blocks 144 one to another. As a non-limiting example, a first of the select line routing structures 148 may be electrically connected to at least some (e.g., all) of the first contact structures 136A of a first row of the first contact structures 136A operatively associated with (e.g., in electrical communication with) the upper select gate structures 156 of the first sub-block 144A of the block 134. As another non-limiting example, a second of the select line routing structures 148 may be electrically connected to at least some (e.g., all) of the first contact structures 136A of a second row of the first contact structures 136A operatively associated with (e.g., in electrical communication with) the upper select gate structures 156 of the second sub-block 144B of the block 134. As an additional non-limiting example, a third of the select line routing structures 148 may be electrically connected to at least some (e.g., all) of the first contact structures 136A of a third row of the first contact structures 136A operatively associated with (e.g., in electrical communication with) the upper select gate structures 156 of the third sub-block 144C of the block 134. As a further non-limiting example, a fourth of the select line routing structures 148 may be electrically connected to at least some (e.g., all) of the first contact structures 136A of a fourth row of the first contact structures 136A operatively associated with (e.g., in electrical communication with) the upper select gate structures 156 of the fourth sub-block 144D of the individual block 134 of the stack structure 102.

As shown in FIG. 1C, for an individual block 134 of the stack structure 102, a first of the select line routing structures 148 may horizontally extend in the X-direction from a first of the deep contact structures 138 within a horizontal area of one of the crest regions 122 proximate the forward staircase structure 114A of the first stadium structure 112A, over the further filled slot structure 111, and to a first row of the first contact structures 136A operatively associated with (e.g., in electrical communication with) the upper select gate structures 156 of the first sub-block 144A of the block 134. The first row of the first contact structures 136A may contact the steps 116 of the forward staircase structure 114A of the first stadium structure 112A. In addition, a second of the select line routing structures 148 may horizontally extend in the X-direction from a second of the deep contact structures 138 within a horizontal area of another one of the crest regions 122 proximate the reverse staircase structure 114B of the first stadium structure 112A, and to a second row of the first contact structures 136A operatively associated with (e.g., in electrical communication with) the upper select gate structures 156 of the second sub-block 144B of the block 134. The second row of the first contact structures 136A may contact the steps 116 of the reverse staircase structure 114B of the first stadium structure 112A. Furthermore, a third of the select line routing structures 148 may horizontally extend in the X-direction from a third of the deep contact structures 138 within the horizontal area of the another one of the crest regions 122 proximate the reverse staircase structure 114B of the first stadium structure 112A, and to a third row of the first contact structures 136A operatively associated with (e.g., in electrical communication with) the upper select gate structures 156 of the third sub-block 144C of the block 134. The third row of the first contact structures 136A may contact the steps 116 of the reverse staircase structure 114B of the first stadium structure 112A. Moreover, a fourth of the select line routing structures 148 may horizontally extend in the X-direction from a fourth of the deep contact structures 138 within a horizontal area of the one of the crest regions 122 proximate the forward staircase structure 114A of the first stadium structure 112A, over the further filled slot structure 111, and to a fourth row of the first contact structures 136A operatively associated with (e.g., in electrical communication with) the upper select gate structures 156 of the fourth sub-block 144D of the block 134. The fourth row of the first contact structures 136A may contact the steps 116 of the forward staircase structure 114A of the first stadium structure 112A.

In addition, for the individual block 134 of the stack structure 102, at least one other of the select line routing structures 148 may horizontally extend in the X-direction from an additional one of the deep contact structure 138 within a horizontal area of the one of the crest regions 122 proximate the forward staircase structure 114A of the first stadium structure 112A, over the further filled slot structure 111, and to yet others of the select line routing structures 148 coupled to others of the first contact structures 136A in electrical communication with vertically lowermost upper select gate structures 156 of the block 134. The yet others of the select line routing structures 148 may individually horizontally extend in the Y-direction, and may individually be coupled to the at least one other of the select line routing structures 148 at least one select line routing junction 148A. The others of the first contact structures 136A may, for example, include four (4) first contact structures 136A, two (2) of which are respectively in electrical communication with the vertically lowermost upper select gate structures 156 of the first sub-block 144A and the second sub-block 144B neighboring a first side of the second additional filled slot structure 110B, and two (2) others of which are respectively in electrical communication with the vertically lowermost upper select gate structures 156 of the third sub-block 144C and the fourth sub-block 144D neighboring a second side of the second additional filled slot structure 110B opposing the first side of the second additional filled slot structure 110B. One (1) of the others of the select line routing structures 148 may horizontally extend in the Y-direction from one (1) of the two (2) of the first contact structures 136A neighboring the first side of the second additional filled slot structure 110B to one (1) of the two (2) others of the first contact structures 136A neighboring the second side of the second additional filled slot structure 110B. In some embodiments, the one (1) of the two (2) of the first contact structures 136A is operatively associated with the first sub-block 144A of the block 134, and the one (1) of the two (2) others of the first contact structures 136A is operatively associated with the fourth sub-block 144D of the block 134. An additional one (1) of the others of the select line routing structures 148 may horizontally extend in the Y-direction from an additional one (1) of the two (2) of the first contact structures 136A neighboring the first side of the second additional filled slot structure 110B to an additional one (1) of the two (2) others of the first contact structures 136A neighboring the second side of the second additional filled slot structure 110B. In some embodiments, the additional one (1) of the two (2) of the first contact structures 136A is operatively associated with the second sub-block 144B of the block 134, and the additional one (1) of the two (2) others of the first contact structures 136A is operatively associated with the third sub-block 144C of the block 134.

The select line routing structures 148 may individually be formed of and include conductive material. As a non-limiting example, the select line routing structures 148 may be formed of and include one or more of at least one metal, at least one alloy, and at least one conductive metal-containing material (e.g., a conductive metal nitride, a conductive metal silicide, a conductive metal carbide, a conductive metal oxide). A material composition of the select line routing structures 148 may be substantially the same as a material composition of the conductive structures 106 of the tiers 108 of the stack structure 102, or the material composition of select line routing structures 148 may be different than the material composition of the conductive structures 106 of the tiers 108 of the stack structure 102. In some embodiments, the select line routing structures 148 are individually formed of and include W. The select line routing structures 148 may individually be homogeneous, or the select line routing structures 148 may individually be heterogeneous.

For an individual block 134 of the stack structure 102, the combination of the first stadium structure 112A, the filled trench 120 within the horizontal area of the first stadium structure 112A, the bridge regions 124 neighboring the first stadium structure 112A, the crest regions 122 neighboring the first stadium structure 112A, the additional filled slot structures 110, the first contact structures 136A, the deep contact structures 138, and the select line routing structures 148 facilitate selective signal transmission to different sub-blocks 144 of the block 134 while also reducing feature (e.g., contact) congestion, routing complexity, and potential failure modes as compared to conventional device configurations. At least due to the combination of the first bridge region 124A, the first additional filled slot structure 110A, the second additional filled slot structure 110B, and the filled trench 120, a first row of the first contact structures 136A landing on the steps 116 of the forward staircase structure 114A and in electrical communication with a first of the select line routing structures 148 (and, hence, a first of the deep contact structures 138) may be coupled to the upper select gate structures 156 of the first sub-block 144A while also being electrically isolated from the upper select gate structures 156 of the second sub-block 144B, the third sub-block 144C, and the fourth sub-block 144D. In addition, at least due to the combination of the first additional filled slot structure 110A, the second additional filled slot structure 110B, and the filled trench 120, a second row of the first contact structures 136A landing on the steps 116 of the reverse staircase structure 114B and in electrical communication with a second of the select line routing structures 148 (and, hence, a second of the deep contact structures 138) may be coupled to the upper select gate structures 156 of the second sub-block 144B while also being electrically isolated from the upper select gate structures 156 of the first sub-block 144A, the third sub-block 144C, and the fourth sub-block 144D. Furthermore, at least due to the combination of the second additional filled slot structure 110B, the third additional filled slot structure 110C, and the filled trench 120, a third row of the first contact structures 136A landing on the steps 116 of the reverse staircase structure 114B and in electrical communication with a third of the select line routing structures 148 (and, hence, a third of the deep contact structures 138) may be coupled to the upper select gate structures 156 of the third sub-block 144C while also being electrically isolated from the upper select gate structures 156 of the first sub-block 144A, the second sub-block 144B, and the fourth sub-block 144D. Moreover, at least due to the combination of the second bridge region 124B, the second additional filled slot structure 110B, the third additional filled slot structure 110C, and the filled trench 120, a fourth row of the first contact structures 136A landing on the steps 116 of the forward staircase structure 114A and in electrical communication with a fourth of the select line routing structures 148 (and, hence, a fourth of the deep contact structures 138) may be coupled to the upper select gate structures 156 of the fourth sub-block 144D while also being electrically isolated from the upper select gate structures 156 of the first sub-block 144A, the second sub-block 144B, and the third sub-block 144C. Positioning at least the second row of the first contact structures 136A and the third row of the first contact structures 136A outside of the horizontal area of the reverse staircase structure 114B (e.g., within the horizontal area of the forward staircase structure 114A) may reduce congestion of the first contact structures 136A within the first stadium structure 112A, and may also reduce processing complexity and mitigate the risk of undesirable damage to features (e.g., the bridge regions 124) of the block 134 during the formation of the first contact structures 136A.

Thus, in accordance with embodiments of the disclosure, a microelectronic device comprises a stack structure, additional dielectric slot structures, and a further dielectric slot structure. The stack structure includes blocks separated from one another by dielectric slot structures. The stack structure further includes a vertically alternating sequence of conductive structures and insulative structures arranged in tiers. At least one of the blocks comprises an upper stadium structure, crest regions, and bridge regions. The upper stadium structure includes staircase structures having steps comprising edges of an upper group of the tiers of the stack structure. The crest regions horizontally neighbor the upper stadium structure in a first direction. The bridge regions are integral with the crest regions and are horizontally interposed between the dielectric slot structures and the upper stadium structure in a second direction orthogonal to the first direction. The additional dielectric slot structures are within a horizontal area of the at least one of the blocks and individually extend in the first direction across a first of the crest regions and at least partially into the upper stadium structure. The additional dielectric slot structures are separated from one another in the second direction and individually vertically extend through the upper group of the tiers of the stack structure. The further dielectric slot structure extends in the second direction across a second of the crest regions of the at least one of the blocks. The further dielectric slot structure horizontally intersects at least one of the additional dielectric slot structures and vertically extends through the upper group of the tiers of the stack structure.

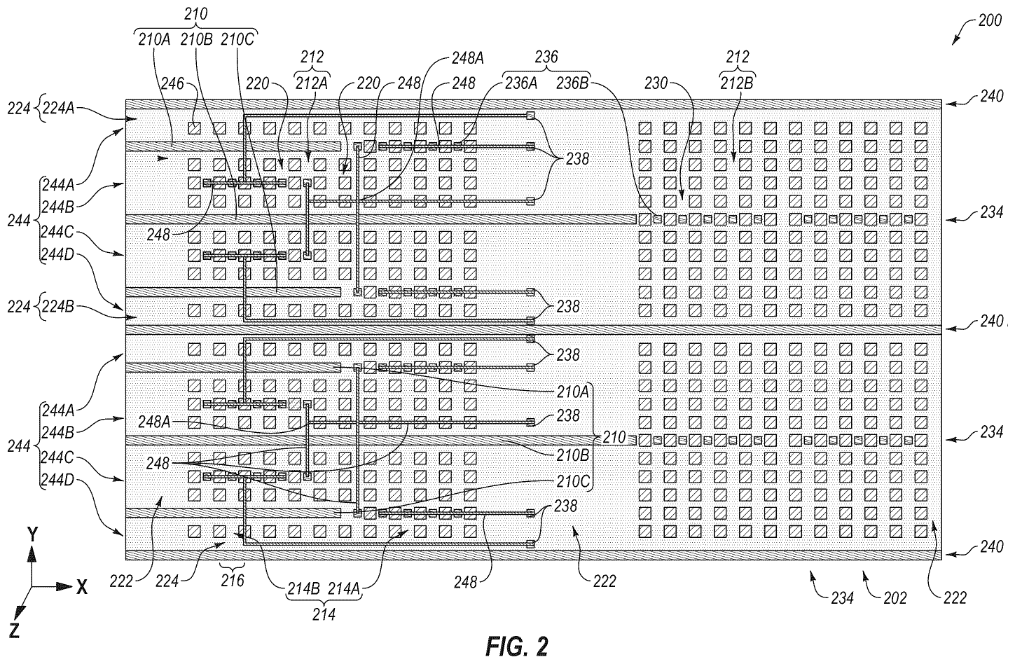

In additional embodiments, the microelectronic device structure 100 has a different configuration than that previously described with reference to FIG. 1A through FIG. 1C. The microelectronic device structure 100 may, for example, be formed to exhibit a configuration such as the configuration depicted in FIG. 2 and described in further detail below. With the description provided below, it will be readily apparent to one of ordinary skill in the art that the structures and devices described herein may be included in relatively larger structures, devices, and systems.

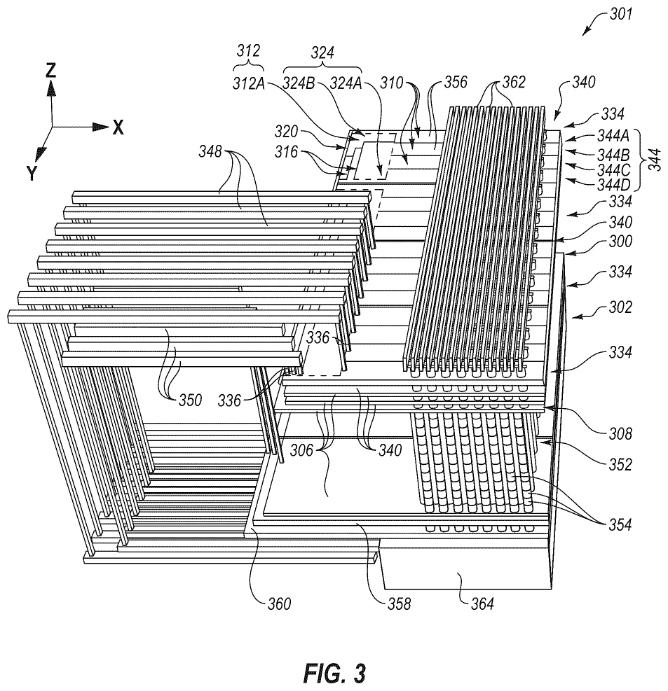

Before referring to FIG. 2, it will be understood that in FIG. 2 and FIG. 3 and the associated description, and features (e.g., regions, materials, structures, devices) functionally similar to previously described features (e.g., previously described materials, structures, devices) are referred to with similar reference numerals incremented by 100. To avoid repetition, not all features shown in FIG. 2 and FIG. 3 are described in detail herein. Rather, unless described otherwise below, a feature shown in one or more of FIG. 2 and FIG. 3 designated by a reference numeral that is a 100 increment of the reference numeral of a feature previously described with reference to one or more of FIG. 1A through FIG. 1C will be understood to be substantially similar to and have substantially the same advantages as the previously described feature. As non-limiting examples, unless described otherwise below, features designated by the reference numerals 236 and 336 in FIG. 2 and FIG. 3, respectively, will be understood to respectively be substantially similar to and have substantially the same advantages as the contact structures 136 previously described herein with reference to FIG. 1A through FIG. 1C. In addition, for clarity and ease of understanding the drawings and related description, some features (e.g., structures, materials, regions, devices) previously described with reference to one or more of FIG. 1A through FIG. 1C may not be depicted in one or more of FIG. 2 and FIG. 3. However, unless described otherwise below, it will be understood that any features of the microelectronic device structure 100 previously described with reference to FIG. 1A through FIG. 1C fall under the scope of this disclosure, and thus may be included in any of the different configurations described below with reference to FIG. 2 and FIG. 3. As a non-limiting example, features substantially similar to the select line routing structures 148 previously described with reference to FIG. 1A through FIG. 1C may be included in the different configurations described below with reference to FIG. 2 and FIG. 3.

FIG. 2 is a simplified, partial top-down view of a microelectronic device structure 200 in accordance with additional embodiments of the disclosure. The microelectronic device structure 200 may be similar to the microelectronic device structure 100 previously described with reference to FIG. 1A through FIG. 1C, except that, for example, blocks 234 of a stack structure 202 of the microelectronic device structure 200 may individually be free of at least further filled slot structure (e.g., corresponding to the further filled slot structure 111 shown in FIGS. 1A and 1C) within a crest region 222 neighboring the forward staircase structure 214A of the first stadium structure 212A thereof; and, within a horizontal area of an individual block 134, the microelectronic device structure 200 may exhibit different configurations of the deep contact structures 238, the select line routing structures 248, and at least one of the additional fill slot structures 210 (e.g., at least the second additional filled slot structure 210B).

For an individual block 234 of the stack structure 202, the filled trench 220 vertically overlying and within a horizontal area of the second stadium structure 212B may, in combination with the second additional filled slot structure 210B, provide a similar electrical isolation effect as the further filled slot structure 111 (FIG. 1A and FIG. 1C) within a horizontal area of an individual block 134 (FIGS. 1A through 1C) of the microelectronic device structure 100 (FIGS. 1A through 1C). For example, the combination of the second stadium structure 212B and the second additional filled slot structure 210B may electrically isolate upper select gate structures (e.g., corresponding to the upper select gate structures 156 previously described with reference to FIGS. 1A through 1C) of the first sub-block 244A and the second sub-block 244B of the block 234 from the upper select gate structures of the third sub-block 244C and the fourth sub-block 244D of the block 234.

As shown in FIG. 2, within a horizontal area of an individual block 234 of the stack structure 202, substantially all of the deep contact structures 238 coupled to the first contact structures 236A within a horizontal areas of the first stadium structure 212A may be horizontally positioned within one (1) of the crest regions 222 horizontally neighboring the forward staircase structure 214A of the first stadium structure 212A. Namely, the unlike the configuration of the microelectronic device structure 100 (FIGS. 1A through 1C), the deep contact structures 238 may be omitted in an additional one (1) of the crest regions 222 horizontally neighboring the reverse staircase structure 214B of the first stadium structure 212A.

For an individual block 234 of the stack structure 202, a first of the select line routing structures 248 may horizontally extend (e.g., in the X-direction) from a first of the deep contact structures 238 within a horizontal area of one of the crest regions 222 proximate the forward staircase structure 214A of the first stadium structure 212A, and to a first row of the first contact structures 236A operatively associated with (e.g., in electrical communication with) the upper select gate structures of the first sub-block 244A of the block 234. The first row of the first contact structures 236A may contact the steps 216 of the forward staircase structure 214A of the first stadium structure 212A. In addition, a second of the select line routing structures 248 may horizontally extend (e.g., in a combination of the X-direction and the Y-direction) from a second of the deep contact structures 238 within a horizontal area of the crest region 222 proximate the forward staircase structure 214A of the first stadium structure 212A, and to a second row of the first contact structures 236A operatively associated with (e.g., in electrical communication with) the upper select gate structures of the second sub-block 244B of the block 234. The second row of the first contact structures 236A may contact the steps 216 of the reverse staircase structure 214B of the first stadium structure 212A. Furthermore, a third of the select line routing structures 248 may horizontally extend (e.g., in a combination of the X-direction and the Y-direction) from a third of the deep contact structures 238 within a horizontal area of the crest region 222 proximate the forward staircase structure 214A of the first stadium structure 212A, and to a third row of the first contact structures 236A operatively associated with (e.g., in electrical communication with) the upper select gate structures of the third sub-block 244C of the block 234. The third row of the first contact structures 236A may contact the steps 216 of the reverse staircase structure 214B of the first stadium structure 212A. Moreover, a fourth of the select line routing structures 248 may horizontally extend (e.g., in the X-direction) from a fourth of the deep contact structures 238 within a horizontal area of the crest region 222 proximate the forward staircase structure 214A of the first stadium structure 212A, and to a fourth row of the first contact structures 236A operatively associated with (e.g., in electrical communication with) the upper select gate structures of the fourth sub-block 244D of the block 234. The fourth row of the first contact structures 236A may contact the steps 216 of the forward staircase structure 214A of the first stadium structure 212A.

In addition, for the individual block 234 of the stack structure 202, at least one other of the select line routing structures 248 may horizontally extend in the X-direction from an additional one of the deep contact structure 138 within a horizontal area of the crest region 222 proximate the forward staircase structure 214A of the first stadium structure 212A, to yet others of the select line routing structures 248 coupled to others of the first contact structures 236A in electrical communication with vertically lowermost upper select gate structures of the block 234. The yet others of the select line routing structures 248 may individually horizontally extend in the Y-direction, and may individually be coupled to the at least one other of the select line routing structures 248 at least one select line routing junction 248A. The others of the first contact structures 236A may, for example, include four (4) first contact structures 236A, two (2) of which are respectively in electrical communication with the vertically lowermost upper select gate structures of the first sub-block 244A and the second sub-block 244B neighboring a first side of the second additional filled slot structure 210B, and two (2) others of which are respectively in electrical communication with the vertically lowermost upper select gate structures of the third sub-block 244C and the fourth sub-block 244D neighboring a second side of the second additional filled slot structure 210B opposing the first side of the second additional filled slot structure 210B. One (1) of the others of the select line routing structures 248 may horizontally extend in the Y-direction from one (1) of the two (2) of the first contact structures 236A neighboring the first side of the second additional filled slot structure 210B to one (1) of the two (2) others of the first contact structures 236A neighboring the second side of the second additional filled slot structure 210B. In some embodiments, the one (1) of the two (2) of the first contact structures 236A is operatively associated with the first sub-block 244A of the block 234, and the one (1) of the two (2) others of the first contact structures 236A is operatively associated with the fourth sub-block 244D of the block 134. An additional one (1) of the others of the select line routing structures 248 may horizontally extend in the Y-direction from an additional one (1) of the two (2) of the first contact structures 236A neighboring the first side of the second additional filled slot structure 210B to an additional one (1) of the two (2) others of the first contact structures 236A neighboring the second side of the second additional filled slot structure 210B. In some embodiments, the additional one (1) of the two (2) of the first contact structures 236A is operatively associated with the second sub-block 244B of the block 234, and the additional one (1) of the two (2) others of the first contact structures 236A is operatively associated with the third sub-block 244C of the block 234.

Thus, in accordance with embodiments of the disclosure, a microelectronic device comprises a stack structure and additional dielectric slot structures. The stack structure includes blocks separated from one another by dielectric slot structures. The blocks individually include a vertically alternating sequence of conductive structures and insulative structures arranged in tiers. At least one of the blocks comprises a pair of crest regions, an upper stadium structure, a pair of bridge regions, and a lower stadium structure. The upper stadium structure is horizontally interposed between the pair of crest regions in a first direction and includes staircase structures having steps comprising edges of an upper group of the tiers. The pair of bridge regions is integral with the pair of crest regions and is horizontally interposed between the dielectric slot structures and the upper stadium structure in a second direction orthogonal to the first direction. The lower stadium structure vertically underlies the upper stadium structure and is horizontally offset from the upper stadium structure in the first direction. The lower stadium structure includes staircase structures having additional steps comprising edges of a lower group of the tiers. The additional dielectric slot structures are within a horizontal area of the at least one of the blocks and vertically extend through the upper group of the tiers to define sub-blocks of the at least one of the blocks. At least two of the additional dielectric slot structures horizontally extend through only one of the pair of crest regions and terminate in the first direction within a horizontal area of the upper stadium structure. At least one other of the additional dielectric slot structures horizontally extend through each of the pair of crest regions and terminate in the first direction at the lower stadium structure.

Microelectronic device structures (e.g., the microelectronic device structure 100 (FIGS. 1A through 1C), the microelectronic device structure 200 (FIG. 2)) of the disclosure may be included in microelectronic devices of the disclosure. For example, FIG. 3 illustrates a partial cutaway perspective view of a portion of a microelectronic device 301 (e.g., a memory device, such as a 3D NAND Flash memory device) including a microelectronic device structure 300. The microelectronic device structure 300 may be substantially similar to one of the microelectronic device structure 100 (FIG. 1A-FIG. 1C) and the microelectronic device structure 200 (FIG. 2) previously described herein.

As shown in FIG. 3, in addition to the features of the microelectronic device structure 300 previously described herein in relation to one or more of the microelectronic device structure 100 (FIG. 1A through FIG. 1C) and the microelectronic device structure 200 (FIG. 2), the microelectronic device 301 may further include cell pillar structures 352 vertically extending through at least some of the blocks 334 of the stack structure 302. The cell pillar structures 352 may be positioned within regions (e.g., memory array regions) of the blocks 334 horizontally offset (e.g., in the X-direction) from the stadium structures 312 (e.g., the first stadium structure 312A) (and, hence, the bridge regions 324) of the blocks 334. Intersections of the cell pillar structures 352 and the conductive structures 306 of the tiers 308 of the stack structure 302 within the horizontal areas of the blocks 334 form strings of memory cells 354 vertically extending through the blocks 334 of the stack structure 302. For each string of memory cells 354, the memory cells 354 thereof may be coupled in series with one another. Within an individual block 334, the conductive structures 306 of some of the tiers 308 of the stack structure 302 may serve as access line structures (e.g., word line structures) for the strings of memory cells 354 within the horizontal area of the block 334. In some embodiments, within an individual block 334, the memory cells 354 formed at the intersections of the conductive structures 306 of some of the tiers 308 and the cell pillar structures 352 comprise so-called “MONOS” (metal-oxide-nitride-oxide-semiconductor) memory cells. In additional embodiments, the memory cells 354 comprise so-called “TANOS” (tantalum nitride-aluminum oxide-nitride-oxide-semiconductor) memory cells, or so-called “BETANOS” (band/barrier engineered TANOS) memory cells, each of which are subsets of MONOS memory cells. In further embodiments, the memory cells 354 comprise so-called “floating gate” memory cells including floating gates (e.g., metallic floating gates) as charge storage structures. The floating gates may horizontally intervene between central structures of the cell pillar structures 352 and the conductive structures 306 of the different tiers 308 of the stack structure 302.

The microelectronic device 301 may further include at least one source structure 360, access line routing structures 350, one or more lower select gate structures 358 (e.g., source select gate (SGS) structures), and digit line structures 362. The digit line structures 362 may vertically overlie and be coupled to the cell pillar structures 352 (and, hence, the strings of memory cells 354). The source structure 360 may vertically underlie and be coupled to the cell pillar structures 352 (and, hence, the strings of memory cells 354). In addition, the contact structures 336 may couple various features of the microelectronic device 301 to one another as shown (e.g., the select line routing structures 348 to the upper select gate structures 356; the access line routing structures 350 to the conductive structures 306 of the tiers 308 of the stack structure 302 underlying the upper select gate structures 356 and defining access line structures of the microelectronic device 301).

The microelectronic device 301 may also include a base structure 364 positioned vertically below the cell pillar structures 352 (and, hence, the strings of memory cells 354). The base structure 364 may include at least one control logic region including control logic devices configured to control various operations of other features (e.g., the strings of memory cells 354) of the microelectronic device 301. As a non-limiting example, the control logic region of the base structure 364 may further include one or more (e.g., each) of charge pumps (e.g., V_{CCP} charge pumps, V_{NEGWL} charge pumps, DVC2 charge pumps), delay-locked loop (DLL) circuitry (e.g., ring oscillators), V_{dd} regulators, drivers (e.g., string drivers), page buffers, decoders (e.g., local deck decoders, column decoders, row decoders), sense amplifiers (e.g., equalization (EQ) amplifiers, isolation (ISO) amplifiers, NMOS sense amplifiers (NSAs), PMOS sense amplifiers (PSAs)), repair circuitry (e.g., column repair circuitry, row repair circuitry), I/O devices (e.g., local I/O devices), memory test devices, MUX, error checking and correction (ECC) devices, self-refresh/wear leveling devices, and other chip/deck control circuitry. The control logic region of the base structure 364 may be coupled to the source structure 360, the access line routing structures 350, the select line routing structures 348, and the digit line structures 362. In some embodiments, the control logic region of the base structure 364 includes CMOS (complementary metal-oxide-semiconductor) circuitry. In such embodiments, the control logic region of the base structure 364 may be characterized as having a “CMOS under Array” (“CuA”) configuration.

Thus, in accordance with embodiments of the disclosure, a memory device comprises a stack structure, additional dielectric slot structures, conductive contact structures, additional conductive contact structures, and select line routing structures. The stack structure comprises blocks separated from one another by dielectric slot structures. The stack structure includes a vertically alternating sequence of conductive structures and insulative structures arranged in tiers. At least one of the blocks includes a memory array region and a stadium structure region. The memory array region has strings of memory cells vertically extending therethrough. The stadium structure region horizontally neighbors the memory array region in a first direction. The stadium structure comprises an upper stadium structure, crest regions, and bridge regions. The upper stadium structure includes staircase structures having steps comprising edges of an upper group of the tiers of the stack structure. The crest regions horizontally neighbor the upper stadium structure in a first direction. The bridge regions are integral with the crest regions and horizontally interposed between the dielectric slot structures and the upper stadium structure in a second direction orthogonal to the first direction. The additional dielectric slot structures are within a horizontal area of the at least one of the blocks, and at least partially define upper select gate structures of the at least one of the blocks. At least two of the additional dielectric slot structures individually extend in the first direction across a first of the crest regions and partially through the upper stadium structure. At least one other of the additional filled dielectric slot structures extend in the first direction across the first of the crest regions and the upper stadium structure, and at least partially through a second of the crest regions. The conductive contact structures are in physical contact with the steps of the upper stadium structure of the at least one of the blocks. The additional conductive contact structures are within the one or more of the first of the crest regions and the second of the crest regions of the at least one of the blocks. The additional conductive contact structures vertically extend completely through the tiers of the stack structure. The select line routing structures extend in the first direction from the additional conductive contact structures to the conductive contact structures.

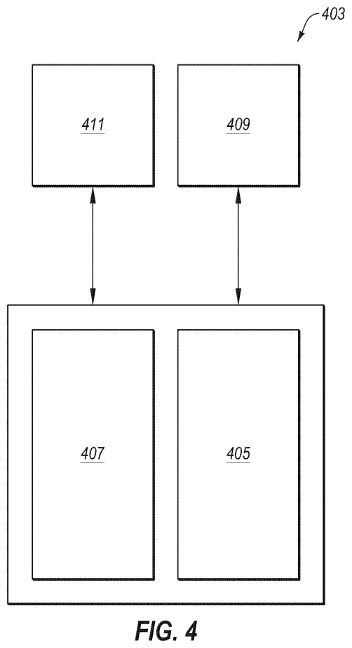

Microelectronic devices structures (e.g., the microelectronic device structure 100 (FIG. 1A through FIG. 1C), the microelectronic device structure 200 (FIG. 2)) and microelectronic devices (e.g., the microelectronic device 301 (FIG. 3)) in accordance with embodiments of the disclosure may be used in embodiments of electronic systems of the disclosure. For example, FIG. 4 is a block diagram of an electronic system 403 according to embodiments of disclosure. The electronic system 403 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPad® or SURFACE® tablet, an electronic book, a navigation device, etc. The electronic system 403 includes at least one memory device 405. The memory device 405 may comprise, for example, one or more of a microelectronic device structure (e.g., the microelectronic device structure 100 (FIG. 1A through FIG. 1C), the microelectronic device structure 200 (FIG. 2)) and a microelectronic device (e.g., the microelectronic device 301 (FIG. 3)). The electronic system 403 may further include at least one electronic signal processor device 407 (often referred to as a “microprocessor”). The electronic signal processor device 407 may, optionally, include one or more of a microelectronic device structure (e.g., the microelectronic device structure 100 (FIG. 1A through FIG. 1C), the microelectronic device structure 200 (FIG. 2)) and a microelectronic device (e.g., the microelectronic device 301 (FIG. 3)). While the memory device 405 and the electronic signal processor device 407 are depicted as two (2) separate devices in FIG. 4, in additional embodiments, a single (e.g., only one) memory/processor device having the functionalities of the memory device 405 and the electronic signal processor device 407 may be included in the electronic system 403. In such embodiments, the memory/processor device may include one or more of a microelectronic device structure (e.g., the microelectronic device structure 100 (FIG. 1A through FIG. 1C), the microelectronic device structure 200 (FIG. 2)) and a microelectronic device (e.g., the microelectronic device 301 (FIG. 3)). The electronic system 403 may further include one or more input devices 409 for inputting information into the electronic system 403 by a user, such as, for example, a mouse or other pointing device, a keyboard, a touchpad, a button, or a control panel. The electronic system 403 may further include one or more output devices 411 for outputting information (e.g., visual or audio output) to a user such as, for example, a monitor, a display, a printer, an audio output jack, a speaker, etc. In some embodiments, the input device 409 and the output device 411 comprise a single touchscreen device that can be used both to input information to the electronic system 403 and to output visual information to a user. The input device 409 and the output device 411 may communicate electrically with one or more of the memory device 405 and the electronic signal processor device 407.

Thus, in accordance with embodiments of the disclosure, an electronic system comprises an input device, an output device, a processor device, and a memory device. The processor device is operably coupled to the input device and the output device. The memory device is operably coupled to the processor device and comprises a stack structure, strings of memory cells, additional dielectric slot structures, and a further dielectric slot structure. The stack structure has tiers. Each tier includes a conductive structure vertically neighboring an insulative structure. The stack structure is divided into blocks separated from one another by dielectric slot structures. At least one of the blocks comprises an upper stadium structure, first elevated regions, and second elevated regions. The upper stadium structure has steps comprising edges of a vertically upper group of the tiers. The first elevated regions neighbor the upper stadium structure in a first horizontal direction. The second elevated regions are integral with the first elevated regions and are interposed between the dielectric slot structures and the upper stadium structure in a second horizontal direction perpendicular to the first horizontal direction. The strings of memory cells vertically extend through the at least one of the blocks. The additional dielectric slot structures are within a horizontal area of the at least one of the blocks and partially vertically extend through the ties of the stack structure. The additional dielectric slot structures individually extend in the first horizontal direction across one of the first elevated regions and at least partially through the upper stadium structure. The additional dielectric slot structures at least partially define sub-blocks of the at least one of the blocks. The further dielectric slot structure extends in the second horizontal direction across an additional one of the first elevated regions of the at least one of the blocks. The further dielectric slot structure partially vertically extends through the tiers of the stack structure and horizontally intersects one of the additional dielectric slot structures and two of the dielectric slot structures.

The structures, devices, and methods of the disclosure advantageously facilitate one or more of improved microelectronic device performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, conventional devices, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalents. For example, elements and features disclosed in relation to one embodiment of the disclosure may be combined with elements and features disclosed in relation to other embodiments of the disclosure.

What is claimed is:

1. A microelectronic device, comprising:
a stack structure comprising blocks separated from one another by dielectric slot structures, the stack structure including a vertically alternating sequence of conductive structures and insulative structures arranged in tiers, at least one of the blocks comprising:
an upper stadium structure including staircase structures having steps comprising edges of an upper group of the tiers of the stack structure;
crest regions horizontally neighboring the upper stadium structure in a first direction; and
bridge regions integral with the crest regions and horizontally interposed between the dielectric slot structures and the upper stadium structure in a second direction orthogonal to the first direction;
additional dielectric slot structures within a horizontal area of the at least one of the blocks and individually extending in the first direction across a first of the crest regions and at least partially into the upper stadium structure, the additional dielectric slot structures separated from one another in the second direction and individually vertically extending through the upper group of the tiers of the stack structure; and
a further dielectric slot structure extending in the second direction across a second of the crest regions of the at least one of the blocks, the further dielectric slot structure horizontally intersecting at least one of the additional dielectric slot structures and vertically extending through the upper group of the tiers of the stack structure.

2. The microelectronic device of claim 1, further comprising:
conductive contact structures in physical contact with the steps of the upper stadium structure of the at least one of the blocks;
additional conductive contact structures within horizontal areas of the crest regions of the at least one of the blocks and vertically extending completely through the stack structure; and
conductive routing structures vertically overlying the stack structure and coupling groups of the conductive contact structures to respective ones of the additional conductive contact structures.

3. The microelectronic device of claim 2, wherein:
some of the groups of the conductive contact structures physically contact the steps of a first of the staircase structures of the upper stadium structure proximate the first of the crest regions; and
some others of the groups of the conductive contact structures physically contact the steps of a second of the staircase structures of the upper stadium structure proximate the second of the crest regions.

4. The microelectronic device of claim 3, wherein:
the some of the groups of the conductive contact structures comprise two rows of the conductive contact structures individually extending in the first direction; and
the some others of the groups of the conductive contact structures comprise two additional rows of the conductive contact structures individually extending in the first direction, the two rows of the conductive contact structures horizontally interposed between the two additional rows of the conductive contact structures in the second direction.

5. The microelectronic device of claim 4, wherein:
the two rows of the conductive contact structures horizontally overlap each of three of the additional dielectric slot structures in the first direction,
the two rows of the conductive contact structures horizontally interposed between two of the three of the additional dielectric slot structures in the second direction, and
one of the three of the additional dielectric slot structures interposed between the two rows of the conductive contact structures in the second direction; and
the two additional rows of the conductive contact structures horizontally overlap only the one of the three of the additional dielectric slot structures in the first direction.

6. The microelectronic device of claim 5, wherein the two additional rows of the conductive contact structures are substantially aligned with the two of the three of the additional dielectric slot structures in the second direction.

7. The microelectronic device of claim 3, wherein:
some of the additional conductive contact structures coupled to the some of the groups of the conductive contact structures are positioned within a horizontal area of the first of the crest regions; and
some others of the additional conductive contact structures coupled to the some others of the groups of the conductive contact structures are positioned within a horizontal area of the second of the crest regions.

8. The microelectronic device of claim 7, wherein:
some of the conductive routing structures horizontally extend in the first direction from the some of the additional conductive contact structures and to the some of the groups of the conductive contact structures; and
some others of the conductive routing structures horizontally extend in the first direction from the some others of the additional conductive contact structures, over the further filled dielectric slot structure, and to the some others of the groups of the conductive contact structures.

9. The microelectronic device of claim 1, wherein the additional dielectric slot structures within the horizontal area of the at least one of the blocks comprise:
a first additional dielectric slot structure horizontally terminating, in the first direction, within a horizontal area of the upper stadium structure;
a second additional dielectric slot structure horizontally terminating, in the first direction, within a horizontal area of the upper stadium structure; and
a third additional dielectric slot structure horizontally interposed between the first additional dielectric slot structure and the second additional dielectric slot structure in the second direction, the third additional dielectric slot structure intersecting the further dielectric slot structure within a horizontal area of the second of the crest regions.

10. The microelectronic device of claim 1, wherein the at least one of the blocks further comprises at least one lower stadium structure vertically underlying the upper stadium structure and having additional steps comprising edges of at least one lower group of the tiers of the stack structure vertically underlying the upper group of the tiers of the stack structure.

11. The microelectronic device of claim 1, wherein the further dielectric slot structure horizontally intersects two of dielectric slot structures horizontally neighboring the at least one of the blocks in the second direction.

12. A microelectronic device, comprising:
a stack structure comprising blocks separated from one another by dielectric slot structures, the blocks individually including a vertically alternating sequence of conductive structures and insulative structures arranged in tiers, at least one of the blocks comprising:
a pair of crest regions;
an upper stadium structure horizontally interposed between the pair of crest regions in a first direction, the upper stadium structure including staircase structures having steps comprising edges of an upper group of the tiers;
a pair of bridge regions integral with the pair of crest regions and horizontally interposed between the dielectric slot structures and the upper stadium structure in a second direction orthogonal to the first direction; and
a lower stadium structure vertically underlying the upper stadium structure and horizontally offset from the upper stadium structure in the first direction, the lower stadium structure including staircase structures having additional steps comprising edges of a lower group of the tiers; and
additional dielectric slot structures within a horizontal area of the at least one of the blocks and vertically extending through the upper group of the tiers to define sub-blocks of the at least one of the blocks,
at least two of the additional dielectric slot structures horizontally extending through only one of the pair of crest regions and terminating in the first direction within a horizontal area of the upper stadium structure, and
at least one other of the additional dielectric slot structures horizontally extending through each of the pair of crest regions and terminating in the first direction at the lower stadium structure.

13. The microelectronic device of claim 12, wherein the at least of a one of the blocks has three of the additional dielectric slot structures within the horizontal area thereof, the three of the additional dielectric slot structures defining four of the sub-blocks of the at least of a one of the blocks.

14. The microelectronic device of claim 13, further comprising:
rows of conductive contact structures in physical contact with the steps of the staircase structures of the upper stadium structure of the at least one of the blocks;
additional contact structures within a horizontal area of an other one of the pair of crest regions and vertically extending completely through the tiers; and
conductive routing structures individually coupling one of the rows of conductive contact structures to a respective one of the additional contact structures.

15. The microelectronic device of claim 14, wherein:
each of the sub-blocks of the at least one of the blocks has a respective one of the rows of conductive contact structures operatively associated therewith; and
two of the rows of conductive contact structures are in physical contact with the steps of a first of the staircase structures of the upper stadium structure; and
two others of the rows of conductive contact structures are in physical contact with the steps of a second of the staircase structures of the upper stadium structure.

16. The microelectronic device of claim 15, wherein the two of the rows of conductive contact structures are horizontally positioned between the two others of the rows of conductive contact structures in the second direction.

17. The microelectronic device of claim 14, wherein at least some of the conductive contact structures of at least one of the rows of conductive contact structures are coupled to one another by way of at least one of the conductive routing structures.

18. A memory device, comprising:
a stack structure comprising blocks separated from one another by dielectric slot structures, the stack structure including a vertically alternating sequence of conductive structures and insulative structures arranged in tiers, at least one of the blocks comprising:
a memory array region having strings of memory cells vertically extending therethrough; and
a stadium structure region horizontally neighboring the memory array region in a first direction and comprising:
an upper stadium structure including staircase structures having steps comprising edges of an upper group of the tiers of the stack structure;
crest regions horizontally neighboring the upper stadium structure in a first direction;
bridge regions integral with the crest regions and horizontally interposed between the dielectric slot structures and the upper stadium structure in a second direction orthogonal to the first direction;
additional filled dielectric slot structures within a horizontal area of the at least one of the blocks at least partially defining upper select gate structures of the at least one of the blocks,
at least two of the additional dielectric slot structures individually extending in the first direction across a first of the crest regions and partially through the upper stadium structure,
at least one other of the additional filled dielectric slot structures extending in the first direction across the first of the crest regions and the upper stadium structure, and at least partially through a second of the crest regions;
conductive contact structures in physical contact with the steps of the upper stadium structure of the at least one of the blocks;
additional conductive contact structures within the one or more of the first of the crest regions and the second of the crest regions of the at least one of the blocks, the additional conductive contact structures vertically extending completely through the tiers of the stack structure; and
select line routing structures extending in the first direction from the additional conductive contact structures to the conductive contact structures.

19. The memory device of claim 18, further comprising a further dielectric slot structure extending in the second direction across the second of the crest regions of the at least one of the blocks, the further dielectric slot structure horizontally intersecting the at least one of the additional filled dielectric slot structures and vertically extending through the upper group of the tiers of the stack structure.

20. The memory device of claim 18, wherein:
the at least one of the blocks further comprises a lower stadium structure vertically underlying the upper stadium structure and horizontally offset from the upper stadium structure in the first direction, the lower staircase structure having additional steps comprising edges of a lower group of the tiers; and
the at least one of the additional filled dielectric slot structures extends in the first direction at least to the lower staircase structure.

21. The memory device of claim 18, wherein all of the additional conductive contact structures are positioned within a horizontal area of the second of the crest regions.

22. The memory device of claim 18, wherein:
some of the additional conductive contact structures are positioned within a horizontal area of the second of the crest regions; and
some others of the additional conductive contact structures are positioned within a horizontal area of the first of the crest regions.

23. The memory device of claim 18, wherein:
the additional filled dielectric slot structures divide the at least one of the blocks into four sub-blocks each including some of the upper select gate structures; and
the four sub-blocks are operatively associated with four rows of the conductive contact structures, at least two of the four rows of the conductive contact structures within a horizontal area of a first of the staircase structures of the upper stadium structure, and at least two others of the four rows of the conductive contact structures within a horizontal area of a second of the staircase structures of the upper stadium structure.

24. The memory device of claim 23, wherein the at least two of the four rows of the conductive contact structures are intervene between the at least two others of the four rows of the conductive contact structures in the second direction.

25. An electronic system, comprising:
an input device;
an output device;
a processor device operably coupled to the input device and the output device; and
a memory device operably coupled to the processor device and comprising:
a stack structure having tiers, each tier including a conductive structure vertically neighboring an insulative structure, the stack structure divided into blocks separated from one another by dielectric slot structures, at least one of the blocks comprising:
an upper stadium structure having steps comprising edges of a vertically upper group of the tiers;
first elevated regions neighboring the upper stadium structure in a first horizontal direction; and
second elevated regions integral with the first elevated regions and interposed between the dielectric slot structures and the upper stadium structure in a second horizontal direction perpendicular to the first horizontal direction;
strings of memory cells vertically extending through the at least one of the blocks;
additional dielectric slot structures within a horizontal area of the at least one of the blocks and partially vertically extending through the ties of the stack structure,
the additional dielectric slot structures individually extending in the first horizontal direction across one of the first elevated regions and at least partially through the upper stadium structure,
the additional dielectric slot structures at least partially defining sub-blocks of the at least one of the blocks; and
a further dielectric slot structure extending in the second horizontal direction across an additional one of the first elevated regions of the at least one of the blocks, the further dielectric slot structure partially vertically extending through the tiers of the stack structure and horizontally intersecting one of the additional dielectric slot structures and two of the dielectric slot structures.

26. The electronic system of claim 25, wherein the memory device comprises a 3D NAND Flash memory device.
